(19) United States
(12) Patent Application Publication
(10) Pub. No.: US 2023/0374376 A1
(43) Pub. Date: Nov. 23, 2023

(54) ELECTROCHROMIC POLYMER HAVING PYRROLE DERIVATIVE AND THIOPHENE

(71) Applicant: AMBILIGHT INC, Grand Cayman (KY)

(72) Inventors: Jianguo MEI, West Lafayette, IN (US); Liyan YOU, West Lafayette, IN (US)

(21) Appl. No.: 18/363,630

(22) Filed: Aug. 1, 2023

Related U.S. Application Data
(63) Continuation of application No. PCT/US2021/055015, filed on Oct. 14, 2021.

(51) Int. Cl. C09K 9/02

(52) U.S. Cl. CPC C09K 9/02; C09K 2211/1483

(57) ABSTRACT

A new electrochromic polymer with yellow or orange or red color at neutral state and a method to form the new electrochromic polymer are disclosed. The disclosed electrochromic polymer has a low oxidation onset potential and a high optical contrast at the wavelength range of 400 nm to 550 nm.

### CROSS-REFERENCE TO RELATED APPLICATIONS

This application is a continuation application of International Patent Application No. PCT/US2021/055015 filed on Oct. 14, 2021, which is incorporated herein by reference in its entirety.

### TECHNICAL FIELD

The present disclosure is related to electrochromic polymers having pyrrole derivatives and thiophenes having a yellow or orange or red color at neutral state, and a method to synthesize the electrochromic polymer.

### BACKGROUND

Electrochromic polymers with yellow or red color at neutral state are of great importance for the fulfillment of a full-color palette, since subtractive primary color sets of both cyan-magenta-yellow (CMY) and red-yellow-blue (RYB) need both yellow and red colors. However, most of the conventional yellow- or red-colored ECPs are electrochemically unstable under repetitive colored-to-transmissive switches. The lack of cycling durability for high-energy absorbing polymers is ascribed to the high oxidation potentials required for the bleaching process. Hence, yellow or orange or red electrochromic polymers with lower oxidation potentials and high optical contrast are desired.

### SUMMARY

The present disclosure is related to an electrochromic polymer comprising a formula of

[(Tr)ₐ-(Ar₁)_{b}-(Ar₂)_{c}-(Ar₃)_{d]n},

wherein,

Tr is a pyrrole-based or a pyrrole derivative-based trimer with a formula of

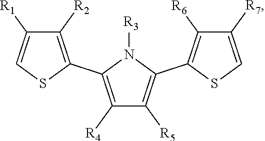

Ar₁ is

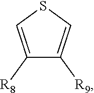

Ar₂ is

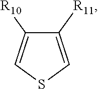

Ar₃ is

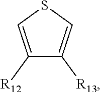

n is an integer greater than 0; a is an integer greater than 0; b, c, and d are integers no less than 0, and a ratio between a and the sum of b, c, and d is between 0.1 to 4 inclusive; each of R₁-R₁₃ is independently selected from, but not limited to, hydrogen, C₁-C₃₀ alkyl, C₂-C₃₀ alkenyl, C₂-C₃₀ alkynyl, C₂-C₃₀ alkylcarbonyl, C₁-C₃₀ alkoxy, C₃-C₃₀ alkoxyalkyl, C₂-C₃₀ alkoxycarbonyl, C₄-C₃₀ alkoxycarbonylalkyl, C₁-C₃₀ alkylthio, C₁-C₃₀ aminylcarbonyl, C₄-C₃₀ aminylalkyl, C₁-C₃₀ alkylaminyl, C₁-C₃₀ alkylsulfonyl, C₃-C₃₀ alkylsulfonylalkyl, C₆-C₁₈ aryl, C₃-C₁₅ cycloalkyl, C₃-C₃₀ cycloalkylaminyl, C₅-C₃₀ cycloalkylalkylaminyl, C₅-C₃₀ cycloalkylalkyl, C₅-C₃₀ cycloalkylalkyloxy, C₁-C₁₂ heterocyclyl, C₁-C₁₂ heterocyclyloxy, C₃-C₃₀ heterocyclylalkyloxy, C₁-C₃₀ heterocyclylalkyloxy, C₁-C₃₀ heterocyclylaminyl, C₅-C₃₀ heterocyclylalkylaminyl, C₂-C₁₂ heterocyclylcarbonyl, C₃-C₃₀ heterocyclylalkyl, C₁-C₁₃ heteroaryl, or C₃-C₃₀ heteroarylalkyl.

In some embodiments, the electrochromic polymer has an oxidation onset potential of lower than 0.6 V with Ag/AgCl as a reference electrode.

In some embodiments, the electrochromic polymer has an optical contrast of higher than 50% at its maximal absorbance wavelength.

In some embodiments, the electrochromic polymer has a maximal absorbance wavelength between 400 to 550nm inclusive.

In some embodiments, Tr is selected from one of the following formulas:

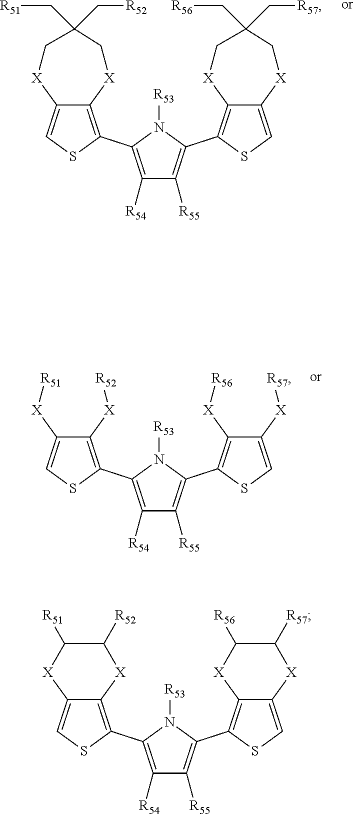

and each of Ar₁, Ar₂, and Ar₃ is independently selected from one of the following formulas:

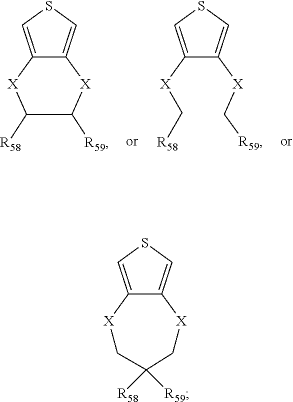

X is S or O; each of R₅₁-R₅₉ is independently selected from, but not limited to, hydrogen, C₁-C₃₀alkyl, C₂-C₃₀ alkenyl, C₂-C₃₀ alkynyl, C₂-C₃₀alkylcarbonyl, C₁-C₃₀alkoxy, C₃-C₃₀alkoxyalkyl, C₂-C₃₀alkoxycarbonyl, C₄-C₃₀alkoxycarbonylalkyl, C₁-C₃₀alkylthio, C₁-C₃₀aminylcarbonyl, C₄-C₃₀aminylalkyl, C₁-C₃₀alkylaminyl, C₁-C₃alkylsulfonyl, C₃-C₃₀alkylsulfonylalkyl, C₆-C₁₈aryl, C₃-C₁₅cycloalkyl, C₃-C₃₀cycloalkylaminyl, C₅-C₃₀cycloalkylalkylaminyl, C₅-C₃₀cycloalkylalkyl, C₅-C₃₀cycloalkylalkyloxy, C₁-C₁₂heterocyclyl, C₁-C₁₂heterocyclyloxy, C₃-C₃₀heterocyclylalkyloxy, C₁-C₃₀heterocyclylalkyloxy, C₁-C₃₀heterocyclylaminyl, C₅-C₃₀heterocyclylalkylaminyl, C₂-C₁₂heterocyclylcarbonyl, C₃-C₃₀heterocyclylalkyl, C₁-C₁₃heteroaryl, or C₃-C₃₀heteroarylalkyl.

In some embodiments, Tr is selected from one of the following formulas:

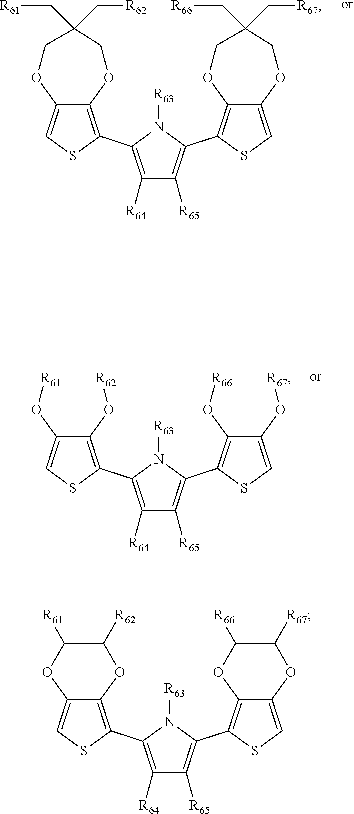

and each of Ar₁, Ar₂, and Ar₃ is independently selected from one of the following formulas:

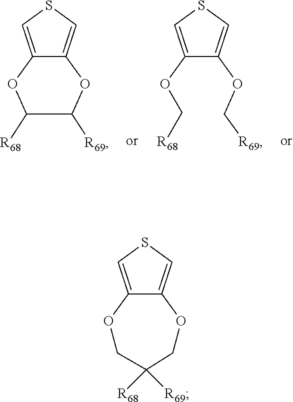

each of R₆₁-R₆₉ is independently selected from, but not limited to, hydrogen, C₁-C₃₀alkyl, C₂-C₃₀alkenyl, C₂-C₃₀alkynyl, C₂-C₃₀alkylcarbonyl, C₁-C₃₀alkoxy, C₃-C₃₀alkoxyalkyl, C₂-C₃₀alkoxycarbonyl, C₄-C₃₀alkoxycarbonylalkyl, C₁-C₊alkylthio, C₁-C₃₀aminylcarbonyl, C₄-C₃₀aminylalkyl, C₁-C₃₀alkylaminyl, C₁-C₃₀alkylsulfonyl, C₃-C₃₀alkylsulfonylalkyl, C₆-C₁₈aryl, C₃-C₁₅cycloalkyl, C₃-C₃₀cycloalkylaminyl, C₅-C₃₀cycloalkylalkylaminyl, C₅-C₃₀cycloalkylalkyl, C₅-C₃₀cycloalkylalkyloxy, C₁-C₁₂heterocyclyl, C₁-C₁₂heterocyclyloxy, C₃-C₃₀heterocyclylalkyloxy, C₁-C₃₀heterocyclylalkyloxy, C₁-C₃₀heterocyclylaminyl, C₅-C₃₀heterocyclylalkylaminyl, C₂-C₁₂heterocyclylcarbonyl, C₃-C₃₀heterocyclylalkyl, C₁-C₁₃heteroaryl, or C₃-C₃₀heteroarylalkyl.

In some embodiments, the electrochromic polymer has a formula of

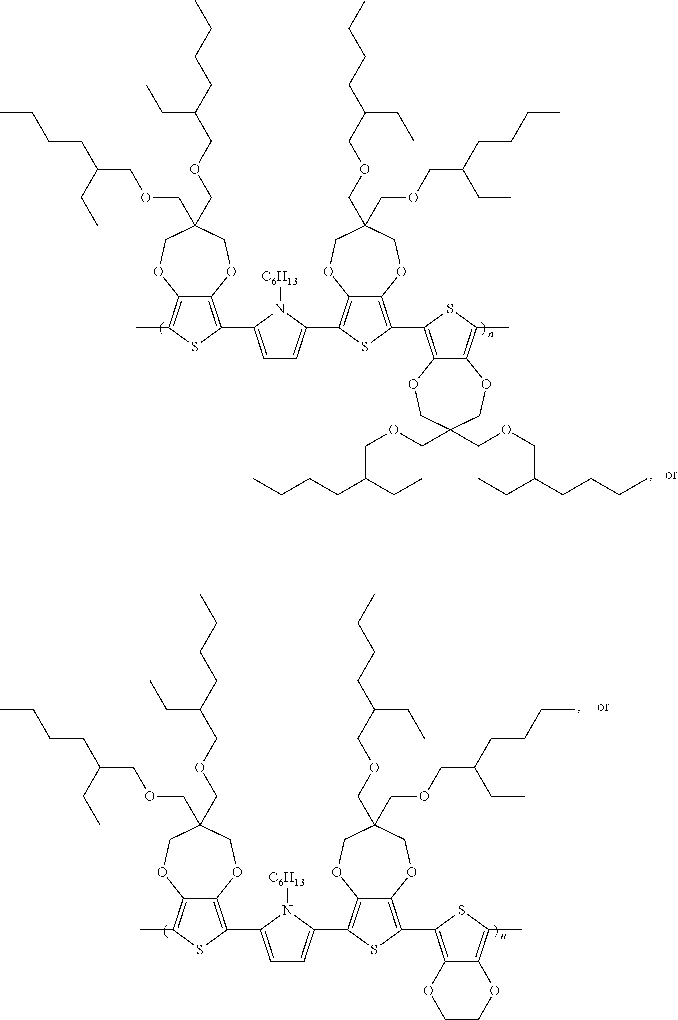

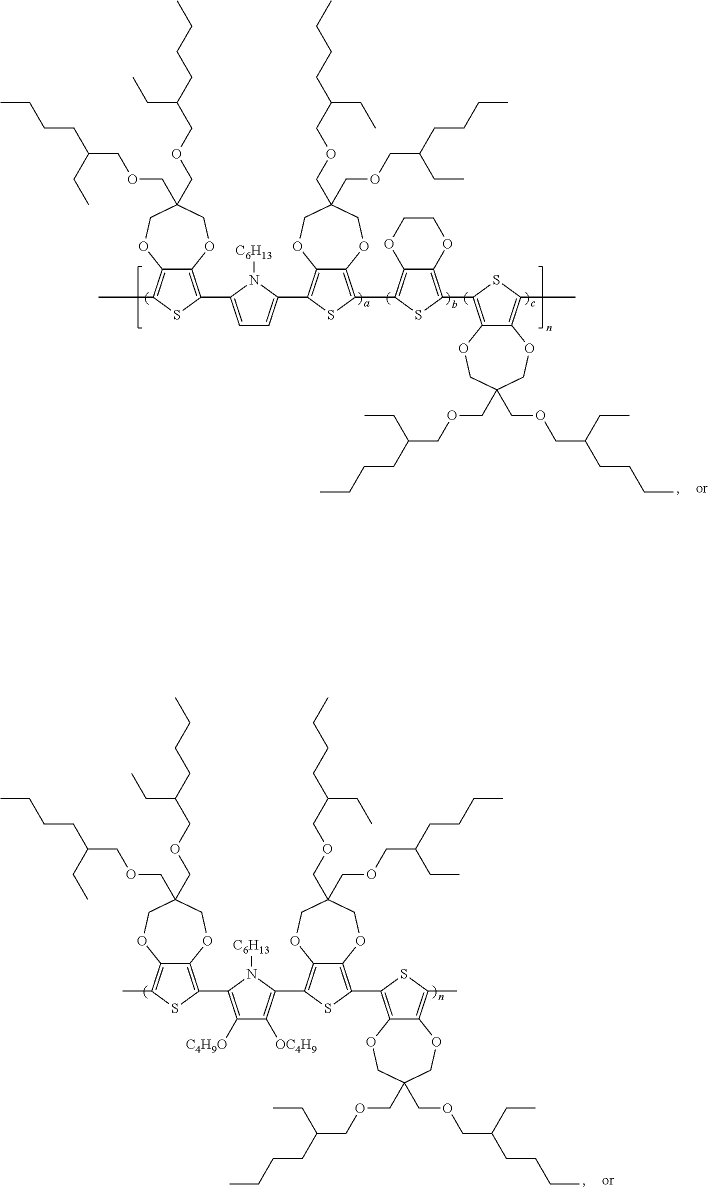

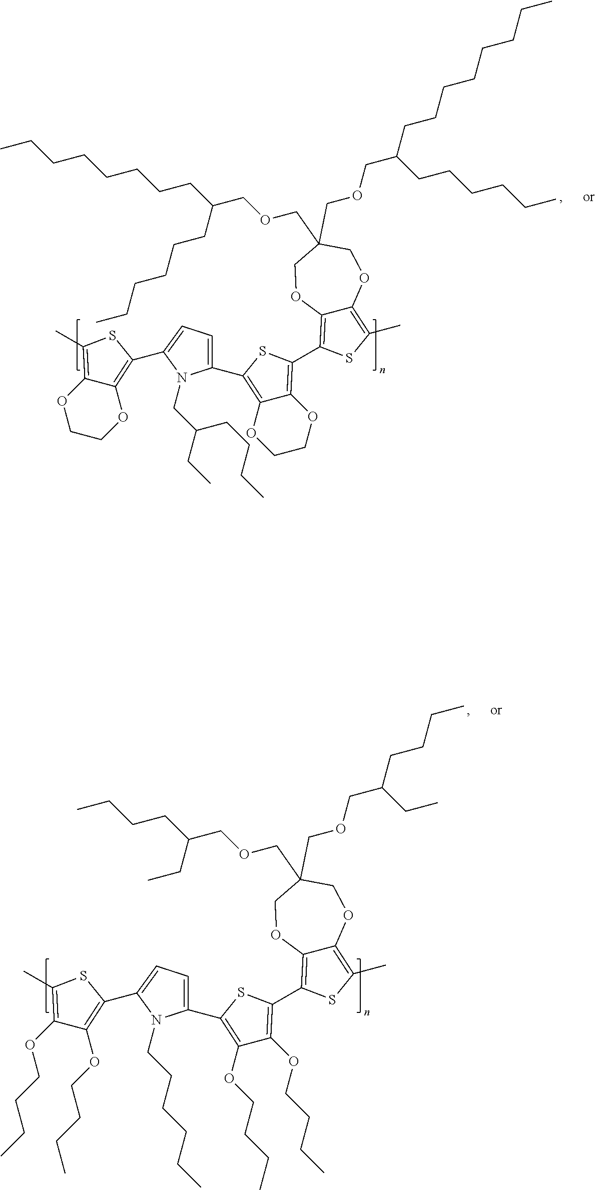

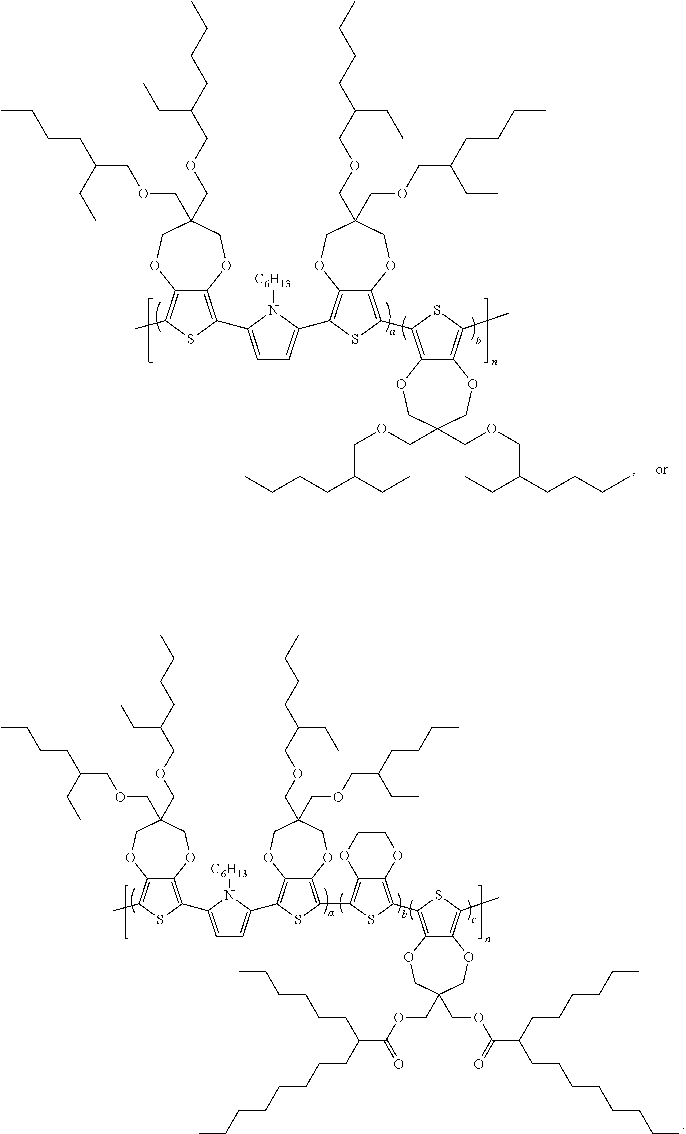

A method for forming the electrochromic polymer is also provided. The method comprises: preparing pyrrole-based or a pyrrole derivative-based thiophene trimer units; preparing the electrochromic polymer by polymerizing the pyrrole or pyrrole derivative-based thiophene trimer units with thiophene units.

A method for forming a pyrrole or pyrrole derivative is also provided. The method comprises contacting diketone with primary amine in the presence of Hexafluoro-2-propanol.

A method for forming diketone derivatives is also provided. The method comprises contacting lithiated thiophene derivatives with N1,N4-dimethoxy-N1,N4-dimethylsuccinamide.

The present disclosure is also related to a device incorporating the disclosed electrochromic polymer.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the invention are utilized, and the accompanying drawings below. For the purpose of illustrating the invention, the drawings show aspects of one or more embodiments of the invention. However, it should be understood that the present invention is not limited to the precise arrangements and instrumentalities shown in the drawings.

FIG. 1 is CV data of an example electrochromic polymer (ECP)-Yellow 1 thin film, according to one example embodiment.

FIG. 2 is the absorbance spectra of the ECP-Yellow 1 thin film at colored and bleached states, according to one example embodiment.

FIG. 3 is the switching kinetics of the ECP-Yellow 1 thin film at 455 nm, according to one example embodiment.

FIG. 4 is CV data of an example ECP-Yellow 2 thin film, according to one example embodiment.

FIG. 5 is the absorbance spectra of the ECP-Yellow 2 thin film at colored and bleached states, according to one example embodiment.

FIG. 6 is the switching kinetics of the ECP-Yellow 2 thin film at 455 nm, according to one example embodiment.

FIG. 7 is CV data of an example ECP-Red 1 thin film, according to one example embodiment.

FIGS. 8(A)-(B) are images of the ECP-Red 1 thin film at colored state (FIG. 8(A)) and bleached state (FIG. 8(B)), according to one example embodiment.

FIG. 9 is the absorbance spectra of the ECP-Red 1 thin film at colored and bleached states, according to one example embodiment.

FIG. 10 is the switching kinetics of ECP-Red 1 thin film at 550 nm, according to one example embodiment.

### DETAILED DESCRIPTION OF EMBODIMENTS

In the following description, certain specific details are set forth in order to provide a thorough understanding of various embodiments of the invention. However, one skilled in the art will understand that the invention may be practiced without these details. Moreover, while various embodiments of the invention are disclosed herein, many adaptations and modifications may be made within the scope of the invention in accordance with the common general knowledge of those skilled in this art. Such modifications include the substitution of known equivalents for any aspect of the invention in order to achieve the same result in substantially the same way.

Unless the context requires otherwise, throughout the present specification and claims, the word “comprise” and variations thereof, such as “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it was individually recited herein. Additionally, the singular forms “a” “an”, and “the” include plural referents unless the context clearly dictates otherwise.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment, but maybe in some instances. Furthermore, the particular features, structures, or characteristics may be combined in any suitable manner in one or more embodiments.

Embodiments of the disclosure are directed to electrochromic polymers (ECPs). Each of the ECPs has a formula of

[(Tr)ₐ-(Ar₁)_{b}-(Ar₂)_{c}-(Ar₃)_{d]n}.

wherein, Tr is a pyrrole-based or a pyrrole derivative-based trimer with a formula of

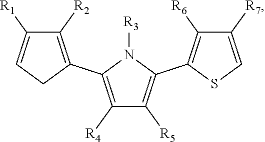

Ar₁ is

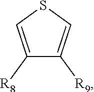

Ar₂ is

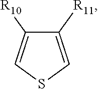

Ar₃ is

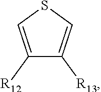

each of R₁-R₁₃ is independently selected from, but not limited to, hydrogen, C₁-C₃₀alkyl, C₂-C₃₀alkenyl, C₂-C₃₀alkynyl, C₂-C₃₀alkylcarbonyl, C₁-C₃₀alkoxy, C₃-C₃₀alkoxyalkyl, C₂-C₃₀alkoxycarbonyl, C₄-C₃₀alkoxycarbonylalkyl, C₁-C₃₀alkylthio, C₁-C₃₀aminylcarbonyl, C₄-C₃₀aminylalkyl, C₁-C₃₀alkylaminyl, C₁-C₃₀alkylsulfonyl, C₃-C₃₀alkylsulfonylalkyl, C₆-C₁₈aryl, C₃-C₁₅cycloalkyl, C₃-C₃₀cycloalkylaminyl, C₅-C₃₀cycloalkylalkylaminyl, C₅-C₃₀cycloalkylalkyl, C₅-C₃₀cycloalkylalkyloxy, C₁-C₁₂heterocyclyl, C₁-C₁₂heterocyclyloxy, C₃-C₃₀heterocyclylalkyloxy, C₁-C₃₀heterocyclylalkyloxy, C₁-C₃₀heterocyclylaminyl, C₅-C₃₀heterocyclylalkylaminyl, C₂-C₁₂heterocyclylcarbonyl, C₃-C₃heterocyclylalkyl, C₁-C₁₃heteroaryl, or C₃-C₃₀heteroarylalkyl; n is an integer greater than 0; a is an integer greater than 0; b, c, and d are integers no less than 0, and a ratio between a and the sum of b, c, and d is between 0.1 to 4 inclusive. In some embodiments, the ratio between a and the sum of b, c, and d is between 0.1 to 2 inclusive. In some embodiments, the ratio between a and the sum of b, c, and d is between 0.1 to 1 inclusive.

In some embodiments, the pyrrole-based or pyrrole derivative-based thiophene trimer unit comprises a pyrrole or pyrrole derivative unit in the middle and two thiophene units on both ends of the pyrrole or pyrrole derivative unit. The ECPs in the present disclosure is formed by polymerization of pyrrole-based or pyrrole derivative-based thiophene trimer units with thiophene units. Although three types of thiophene units are listed in the formula described above to be polymerized with pyrrole-based or pyrrole derivative-based thiophene trimer units, more or fewer than three types of thiophene units to be polymerized with pyrrole-based or pyrrole derivative-based thiophene trimer units are possible and contemplated in this disclosure. The polymerization can be random polymerization or alternating polymerization comprising a repeating unit with a specific sequence. In some embodiments, the repeating unit for the disclosed ECPs comprises one pyrrole-based or pyrrole derivative-based thiophene trimer unit. In some embodiments, the disclosed ECPs comprises more than one pyrrole-based or pyrrole derivative-based thiophene trimer unit conjugated to each other. In some embodiments, the disclosed ECPs comprises pyrrole-based or pyrrole derivative-based thiophene trimer units spaced/separated by at least one thiophene unit.

The ECPs in the present disclosure show yellow or orange or red colors at their neutral states and nearly colorless at their oxidized states. Because of the introduction of pyrrole or pyrrole derivative units, the disclosed ECPs have the advantages of low oxidation onset potential, which typically leads to outstanding cycling durability.

The electrochromic polymer in the present disclosure has an oxidation onset potential of lower than 0.6 V with Ag/AgCl as a reference electrode. In some embodiments, the electrochromic polymer has an oxidation onset potential lower than 0.4 V vs. Ag/AgCl.

The electrochromic polymer in the present disclosure has a maximal absorbance wavelength between 400 nm to 550 nm inclusive. In some embodiments, the electrochromic polymer presents a yellow color at neutral state. In some embodiments, the electrochromic polymer presents an orange color at neutral state. In some embodiments, the electrochromic polymer presents a red color at neutral state.

The electrochromic polymer in the present disclosure has an optimal optical contrast of higher than 50% at its maximal absorbance wavelength. In some embodiments, the electrochromic polymer has an optimal optical contrast of higher than 60% at its maximal absorbance wavelength. In some embodiments, the electrochromic polymer may have an optimal optical contrast of higher than 70%, 80%, 90%, 95%, or up to 100% at its maximal absorbance wavelength, or between any two of the above numbers.

In some embodiments, the ECPs have a repeating unit comprising one pyrrole-based or pyrrole derivative-based thiophene trimer unit with one thiophene unit. In some embodiments, the ECPs have a repeating unit comprising one pyrrole-based or pyrrole derivative-based thiophene trimer unit with three thiophene units. In some embodiments, the ECPs have a repeating unit comprising one pyrrole-based or pyrrole derivative-based thiophene trimer unit with five thiophene units. In some embodiments, the ECPs have a repeating unit comprising one pyrrole-based or pyrrole derivative-based thiophene trimer unit with ten thiophene units. In some embodiments, the ECPs have a repeating unit comprising more than one pyrrole-based or pyrrole derivative-based thiophene trimer units together with thiophene units.

In some embodiments, Tr is selected from the one of following formulas:

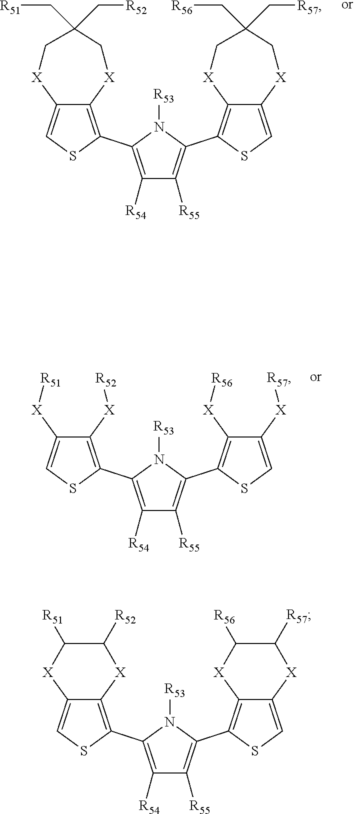

and each of Ar₁, Ar₂, and Ar₃ is independently selected from the one of following formulas:

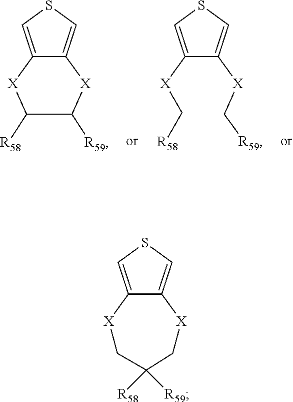

X is S or O; each of R₅₁-R₅₉ is independently selected from, but not limited to, hydrogen, C₁-C₃₀alkyl, C₂-C₃₀alkenyl, C₂-C₃₀alkynyl, C₂-C₃₀alkylcarbonyl, C₁-C₃₀alkoxy, C₃-C₃₀alkoxyalkyl, C₂-C₃₀alkoxycarbonyl, C₄-C₃₀alkoxycarbonylalkyl, C₁-C₃₀alkylthio, C₁-C₃₀aminylcarbonyl, C₄-C₃₀aminylalkyl, C₁-C₃₀alkylaminyl, C₁-C₃₀alkylsulfonyl, C₃-C₃₀alkylsulfonylalkyl, C₆-C₁₈aryl, C₃-C₁₅cycloalkyl, C₃-C₃₀cycloalkylaminyl, C₅-C₃₀cycloalkylalkylaminyl, C₅-C₃₀cycloalkylalkyl, C₅-C₃₀cycloalkylalkyloxy, C₁-C₁₂heterocyclyl, C₁-C₁₂heterocyclyloxy, C₃-C₃₀heterocyclylalkyloxy, C₁-C₃₀heterocyclylalkyloxy, C₁-C₃₀heterocyclylaminyl, C₅-C₃₀heterocyclylalkylaminyl, C₂-C₁₂heterocyclylcarbonyl, C₃-C₃₀heterocyclylalkyl, C₁-C₁₃heteroaryl, or C₃-C₃₀heteroarylalkyl.

In some embodiments, all the Xs are O, the thiophene units comprise propylenedioxythiophenes (ProDOTs) or ethylenedioxythiophenes (EDOTs) units, Tr is selected from one of the following formulas:

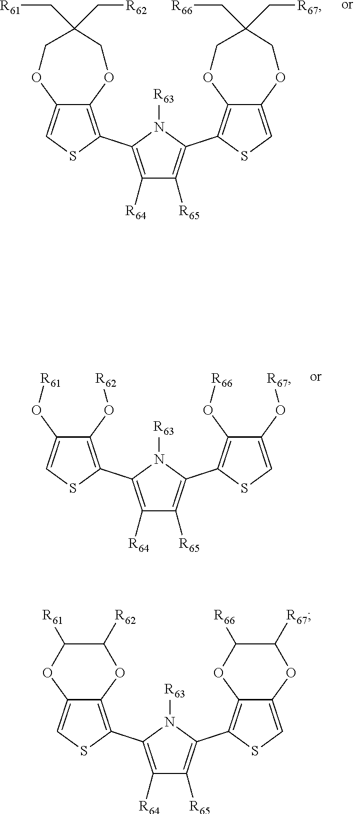

and each of Ar₁, Ar₂, and Ar₃ is independently selected from one of the following formulas:

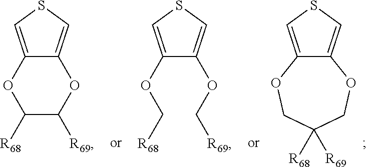

each of R₆₁-R₆₉ is independently selected from, but not limited to, hydrogen, C₁-C₃₀alkyl, C₂-C₃₀alkenyl, C₂-C₃₀alkynyl, C₂-C₃₀alkylcarbonyl, C₁-C₃₀alkoxy, C₃-C₃₀alkoxyalkyl, C₂-C₃₀alkoxycarbonyl, C₄-C₃₀alkoxycarbonylalkyl, C₁-C₃₀alkylthio, C₁-C₃₀aminylcarbonyl, C₄-C₃₀aminylalkyl, C₁-C₃₀alkylaminyl, C₁-C₃₀alkylsulfonyl, C₃-C₃₀alkylsulfonylalkyl, C₆-C₁₈aryl, C₃-C₁₅cycloalkyl, C₃-C₃₀cycloalkylaminyl, C₅-C₃₀cycloalkylalkylaminyl, C₅-C₃₀cycloalkylalkyl, C5-C₃₀cycloalkylalkyloxy, C₁-C₁₂heterocyclyl, C₁-C₁₂heterocyclyloxy, C₃-C₃₀heterocyclylalkyloxy, C₁-C₃₀heterocyclylalkyloxy, C₁-C₃₀heterocyclylaminyl, C₅-C₃₀heterocyclylalkylaminyl, C₂-C₁₂ heterocyclylcarbonyl, C₃-C₃heterocyclylalkyl, C₁-C₁₃ heteroaryl, or C₃-C₃₀heteroarylalkyl.

The present disclosure is also related to a method for forming the electrochromic polymer disclosed here. The method comprises: preparing pyrrole-based or pyrrole derivative-based thiophene trimer units, and preparing the ECP by polymerizing the trimer units with thiophene units. The polymerization can be random polymerization or alternating polymerization comprising a repeating unit with a specific sequence.

The present disclosure is also related to a method for forming diketone derivatives. The method comprises contacting lithiated thiophene derivatives with N1,N4-dimethoxy-N1,N4-dimethylsuccinamide. The present disclosure is also related to a method for forming a pyrrole or pyrrole derivative. The method comprises ring closure of diketone with primary amine using Hexafluoro-2-propanol as a solvent.

### EMBODIMENTS

### Embodiment 1—a yellow electrochromic polymer (ECP-Yellow 1) formed by alternating polymerization

In one embodiment, the electrochromic polymer (ECP-Yellow 1) has a formula of

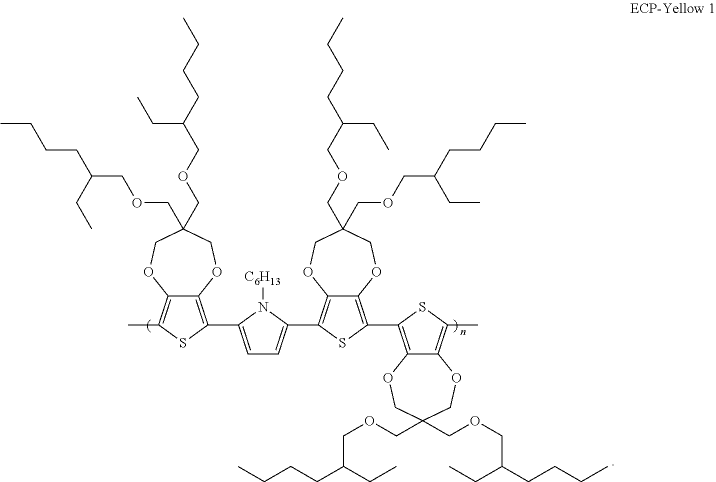

ECP-Yellow 1 is synthesized by preparing a pyrrole derivative-based thiophene trimer unit and polymerizing the pyrrole derivative-based thiophene trimer unit with a Propylenedioxythiophene (ProDOT) unit. The detailed method includes the following steps:

Step 1-1: Make a diketone derivative product (compound 3) with the following reaction:

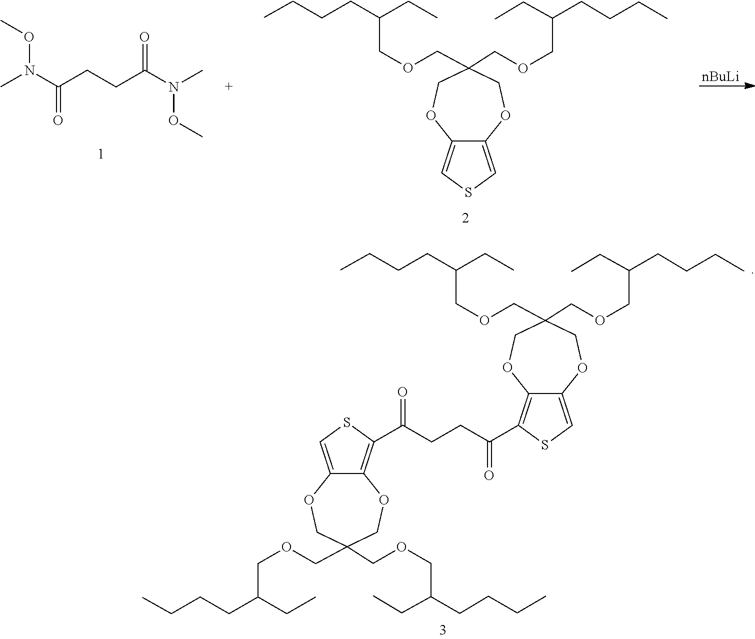

Propylenedioxythiophene(ProDOT) (compound 2) (2.8g, 2.6 eq) is added into a Schlenk tube. The tube is kept under vacuum for about 15 minutes and then purged with N₂. The process described above is repeated for three cycles. Then 10 mL anhydrous tetrahydrofuran (THF) is added into the tube with a syringe. The solution is kept at −78° C. and then 2.5 mL nBuLi solution (2.5M in hexane) is added slowly over 20-30 minutes into the tube at −78° C. The solution is slowly warmed up to 0° C. and reacted for 30 minutes, then cooled to −78° C. again. N1,N4-dimethoxy-N1,N4-dimethylsuccinamide (compound 1) is dissolved in 3 mL dry THF and then added slowly over 30-50 minutes into the Schlenk tube at −78° C. The solution is reacted at −78° C. for 2 hours and then is warmed up to room temperature. The reaction is quenched with acetic acid solution and water and then an organic product is extracted with EtOAc. The organic product is dried and vacuumed to remove the remaining solvent. The resulting mixture is purified by silica gel chromatography to get the diketone derivative product (compound 3, yield-80%).

Step 1-2: Make a pyrrole derivative-based thiophene trimer (compound 4)

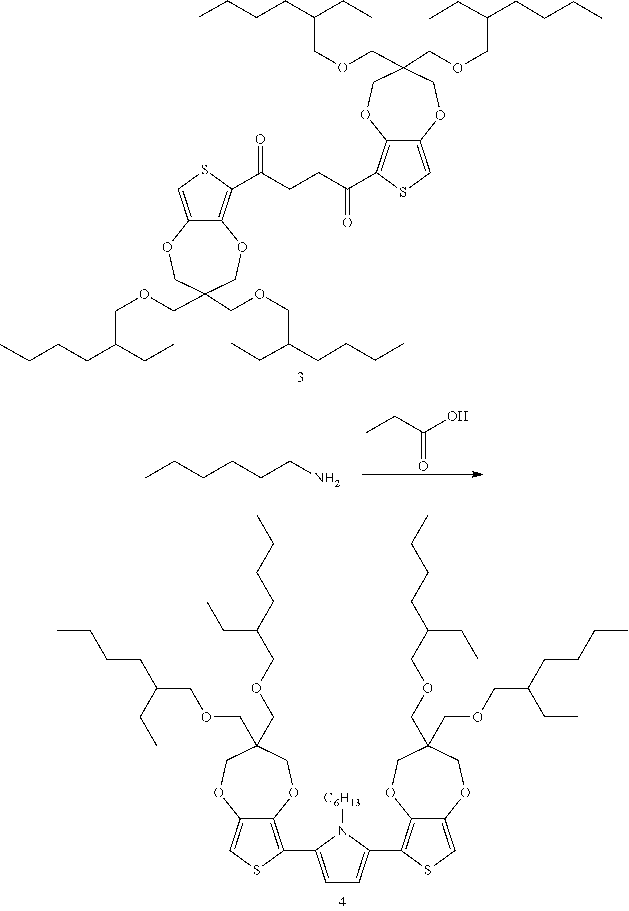

Diketone compound 3 (400 mg, leq), 1-hexanamine (126 mg, 3 eq), propanoic acid (10 mg, 0.3 eq), 4 mL anhydrous toluene is added into a flask. The mixture is bubbled with nitrogen for 10 min to remove air. Then the mixture is heated to 110° C. under nitrogen and reacts for 12 hours. The mixture is cooled to room temperature and washed with water. The organic phase is collected, and the remaining solvent is removed with rotovap. The resulting mixture is purified by silica gel chromatography to get the pyrrole derivative-based thiophene trimer, compound 4 (yield-80-90%).

Step 1-3: Make ECP-Yellow 1 with alternating polymerization

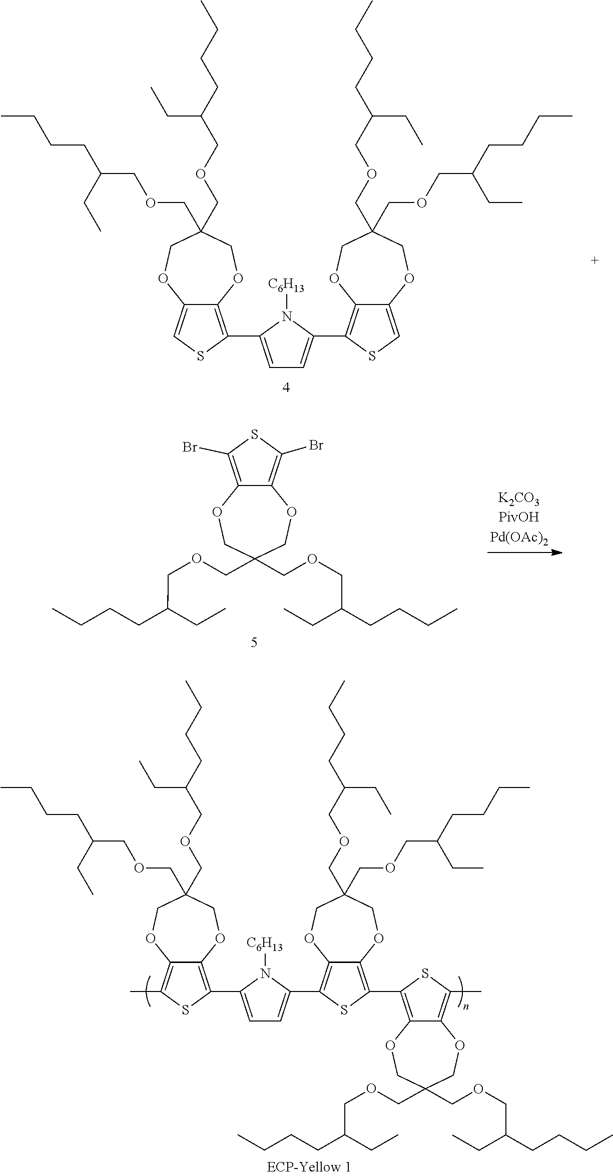

Propylenedioxythiophene-2Br (ProDOT-2Br, compound 5, 1.0 eq), compound 4 (1.0 eq), K₂CO₃ (2.6 eq.), PivOH (0.3 eq.), and Pd(OAc)₂ (0.02 eq.) are added to a Schlenk tube. The tube is kept under vacuum for about 15 minutes and then purged with N₂. The process described above is repeated for three cycles. Then, nitrogen degassed solvent Dimethylacetamide (DMAc) is added into the tube for reaction at 120° C. for 12 hours under nitrogen. Transfer the hot reaction mixture to a 1:1 mixture solvent of CH3OH and 1M HCl with stirring. Filter to get solid. The solid is dissolved in chloroform and washed with 1M HCl solution. The organic phase is concentrated and precipitated with CH₃OH. Filter and dry to get ECP-Yellow 1. Yield is about 80-100%.

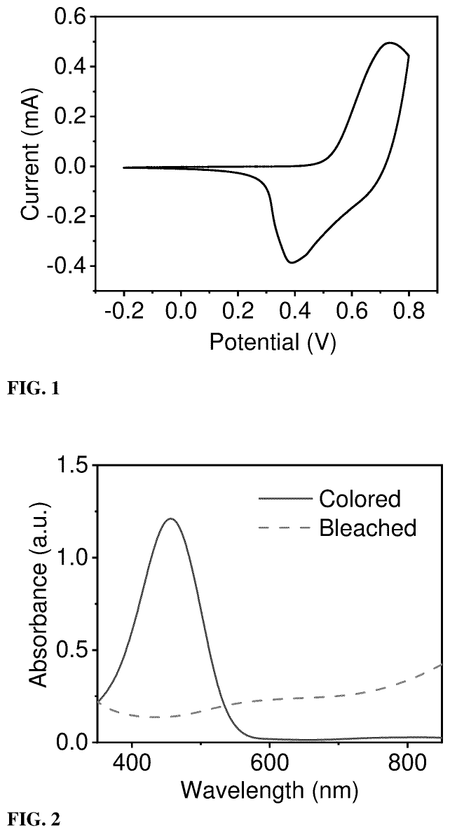

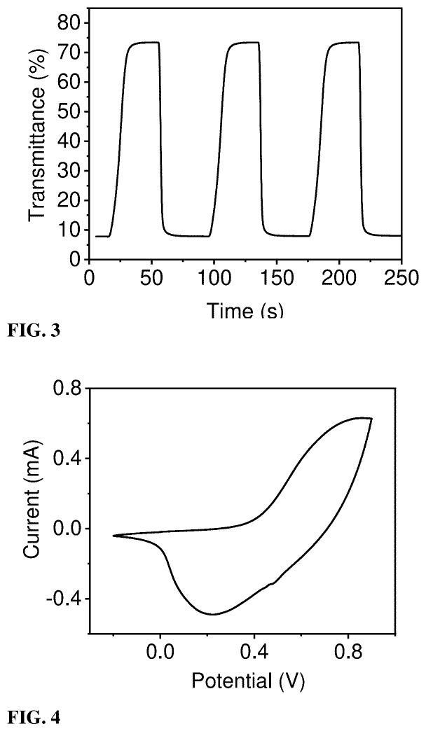

The obtained ECP-Yellow 1 is dissolved in chloroform with a concentration of 22 mg/ml. The ECP-Yellow 1 chloroform solution is spin-coated onto an ITO-coated glass substrate. The performance of the resulting ECP-Yellow 1 thin film is tested in a three-electrode system with Ag/AgCl as the reference electrode, 1M LiPF₆/PC as the electrolyte, and Pt wire as the counter electrode. As shown in FIG. 1, the ECP-Yellow 1 thin film has a low oxidation onset potential of 0.52 V vs. Ag/AgCl. And the electrochromic polymer shows yellow color with maximal absorbance at 455 nm at a colored state and low absorbance within visible light range (350 nm-800nm) at a bleached state (shown in FIG. 2). The optimal optical contrast at 455 nm is as high as 66% (shown in FIG. 3).

### Embodiment 2—a yellow electrochromic polymer (ECP-Yellow 2) formed by alternating polymerization

In one embodiment, the electrochromic polymer (ECP-Yellow 2) has a formula of

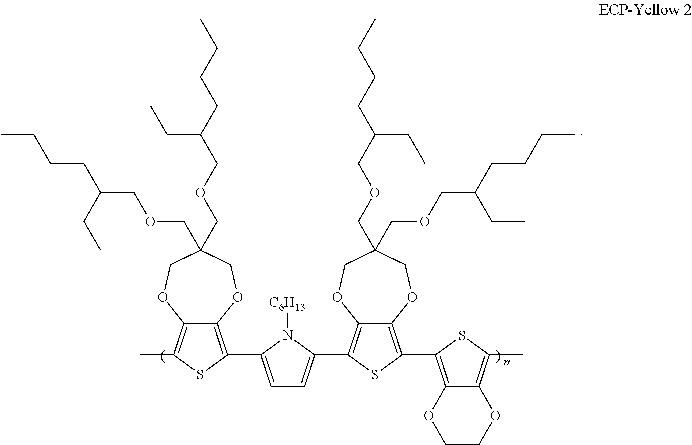

ECP-Yellow 2 is synthesized by preparing a pyrrole derivative-based thiophene trimer unit and then polymerizing the pyrrole-based thiophene trimer unit with an Ethylenedioxythiophene (EDOT) unit. The detailed method includes the following steps:

Step 2-1: Make a diketone derivative product (compound 3)

Same as step 1-1.

Step 2-2: Make a pyrrole derivative-based thiophene trimer (compound 4)

Same as step 1-2.

Step 2-3: Make ECP-Yellow 2 with alternating polymerization

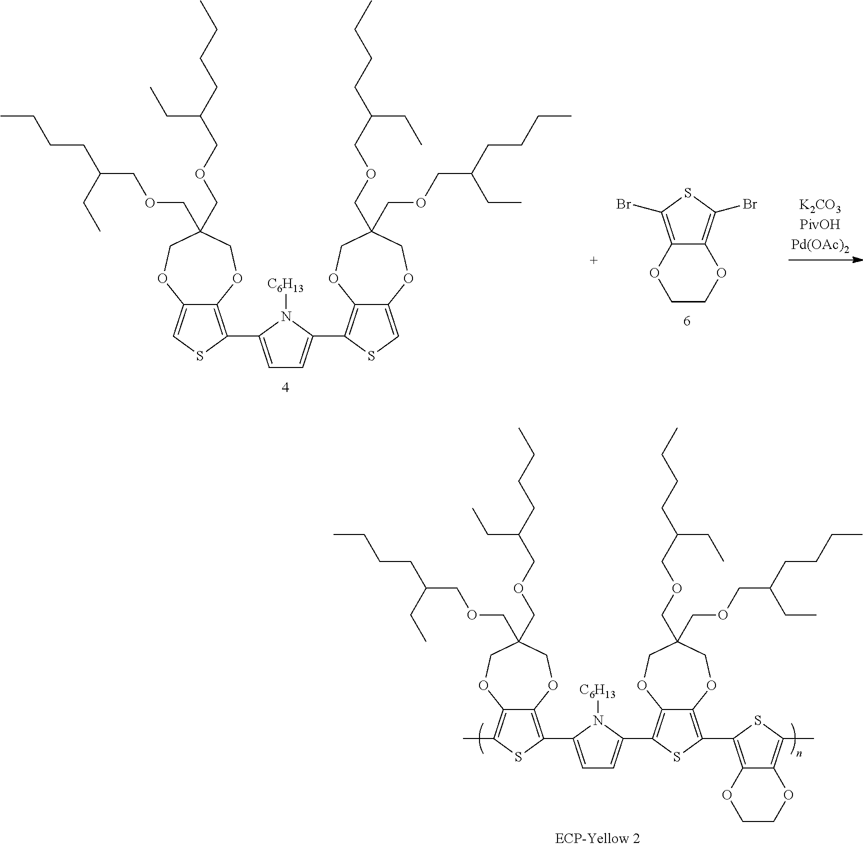

Same as step 1-3, except that 3,4-Ethylenedioxythiophene-2Br (EDOT-2Br) compound 6 (1.0eq), pyrrole derivative-based thiophene trimer compound 4 (1.0 eq), K₂CO₃ (2.6 eq.), PivOH (0.3 eq.), and Pd(OAc)₂ (0.02 eq.) are added to a Schlenk tube for the reaction.

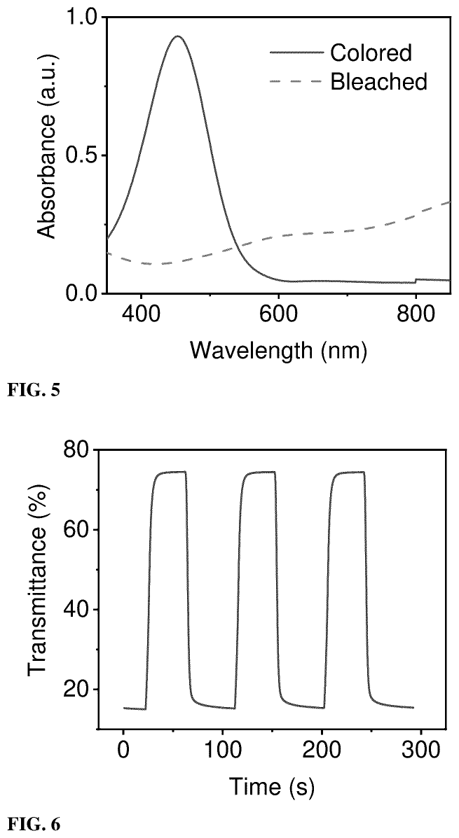

The obtained ECP-Yellow 2 is dissolved in chloroform with a concentration of 30 mg/ml. The ECP-Yellow 2 chloroform solution is spin-coated onto an ITO-coated glass substrate. The performance of the resulting ECP-Yellow 2 thin film is tested in a three-electrode system with Ag/AgCl as the reference electrode, 1M LiPF₆/PC as the electrolyte, and Pt wire as the counter electrode. As shown in FIG. 4, the exemplary electrochromic polymer has a very low oxidation onset potential of 0.38 V vs. Ag/AgCl. And the electrochromic polymer shows yellow color with maximal absorbance at 455 nm at a colored state and low absorbance within the visible light range (350 nm-800 nm) at a bleached state (shown in FIG. 5). The optimal optical contrast at 455 nm is as high as 66% (shown in FIG. 6).

### Embodiment 3—a yellow electrochromic polymer (ECP-Yellow 3) formed by random polymerization

In one embodiment, the electrochromic polymer (ECP-Yellow 3) has a formula of

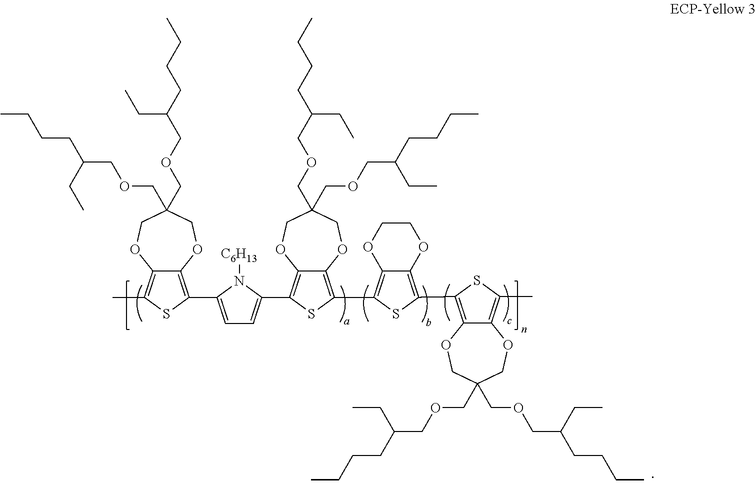

ECP-Yellow 3 is synthesized by preparing a pyrrole derivative-based trimer unit and then polymerizing the pyrrole derivative-based trimer unit with a ProDOT unit and a EDOT unit. The detailed method includes the following steps:

Step 3-1: Make a diketone derivative product (compound 3)

Same as step 1-1.

Step 3-2: Make a pyrrole derivative-based trimer (compound 4)

Same as step 1-2.

Step 3-3: Make ECP-Yellow 3

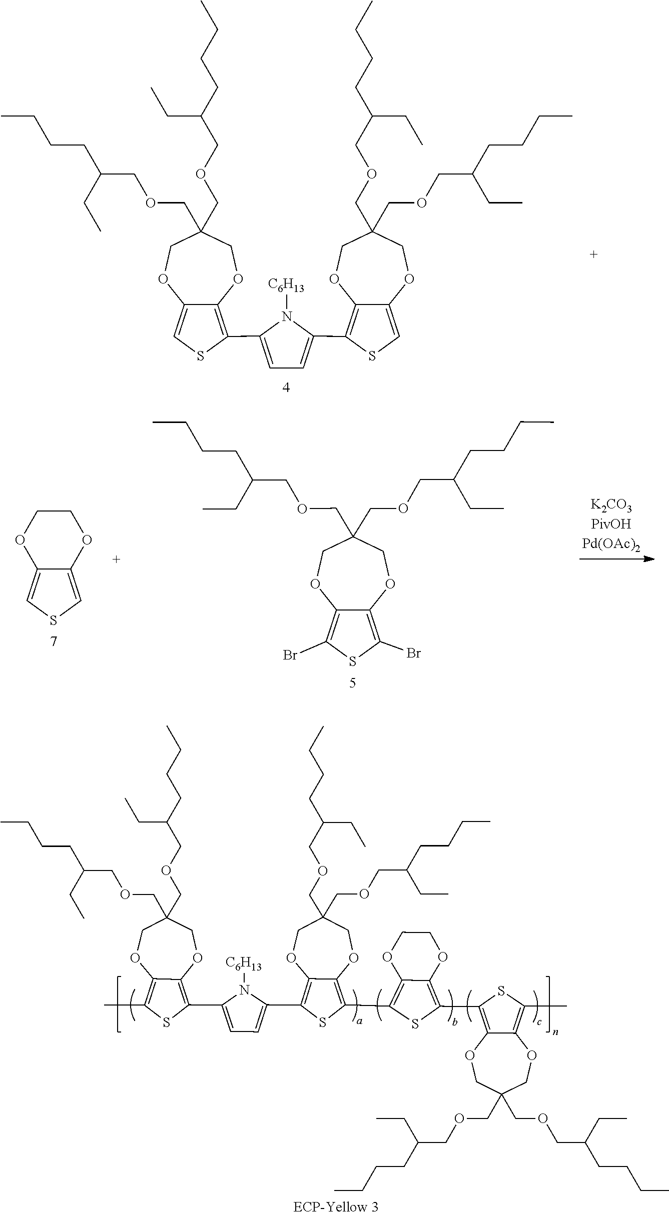

Same as step 1-3, except that Propylenedioxythiophene-2Br (ProDOT-2Br) compound 5 (1.0 eq), 3,4-Ethylenedioxythiophene (EDOT) compound 7 (0.33 eq), pyrrole derivative-based thiophene trimer compound 4 (0.67 eq), K₂CO₃ (2.6 eq.), PivOH (0.3 eq.), and Pd(OAc)₂ (0.02 eq.) are added to a Schlenk tube for the reaction.

### Embodiment 4—yellow electrochromic polymer (ECP-Yellow 4) formed by alternating polymerization

In one embodiment, the electrochromic polymer (ECP-Yellow 4) has a formula of

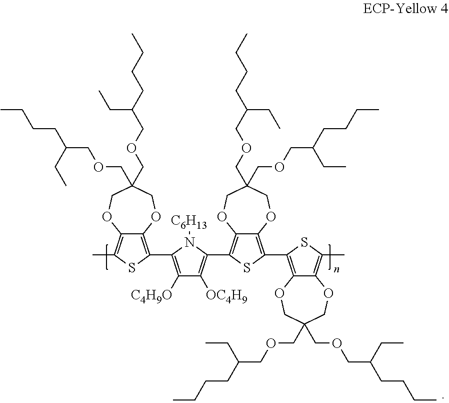

ECP-Yellow 4 is synthesized by preparing a pyrrole derivative-based trimer unit and then polymerizing the pyrrole derivative-based trimer unit with a ProDOT unit. The detailed method includes the following steps:

Step 4-1: Make a diketone derivative (compound 9). Compound 9 can be made through 2 different routes.

Route 4-1A: Make compound 9 via reacting ProDOT with compound 8.

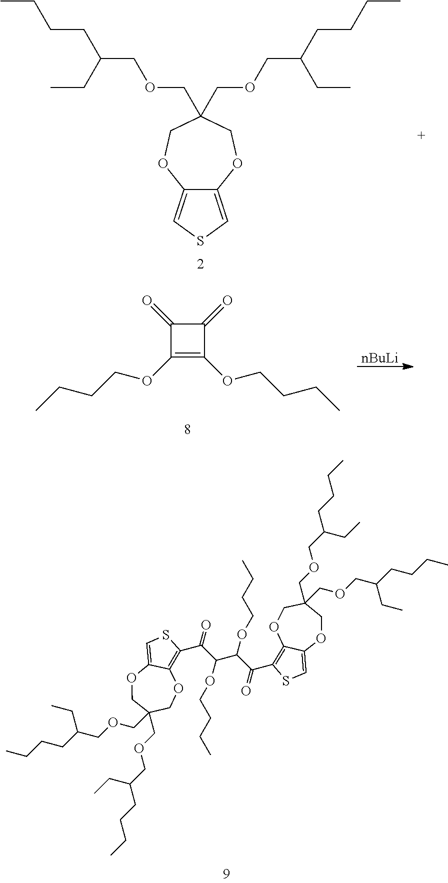

Propylenedioxythiophene(ProDOT) compound 2 (3.0 g, 3 eq) is added into a Schlenk tube. The tube is kept under vacuum for about 15 minutes and then purged with N₂. The process described above is repeated for three cycles. Then anhydrous tetrahydrofuran (THF) of 15 mL is added into the tube with a syringe. The solution is kept at −78° C. and then 2.7 mL nBuLi solution (2.5M in hexane) is added. The solution is further warmed up to room temperature and then 3,4-dibutoxycyclobut-3-ene-1,2-dione (compound 8, 1 eq) is added. After reacting for one hour, the reaction is quenched with NH₄Cl solution. The resulting solution is extracted with EtOAc to obtain an organic phase. The organic phase is dried, and the solvent is removed under vacuum. The crude product is purified by silica gel chromatography to get the diketone derivative product (compound 9) (yield-60-95%).

Route 4-1B: Make a diketone derivative (compound 9) via a 3-step reaction.

Route 4-1B-1^{st} step: Make compound 12

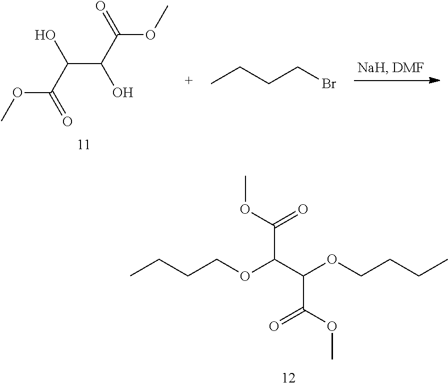

Dimethyl tartrate (compound 11, 1.0 eq) is added to DMF solution. Sodium hydride (2.2 eq) is added into the solution slowly. Then 1-Bromobutane is added into the solution for reaction. An organic phase is extracted with DCM and water. The organic phase is collected, and the solvent is removed. The crude product is purified by silica gel chromatography (yield-50-85%).

Route 4-1B-2nd step: Make compound 13

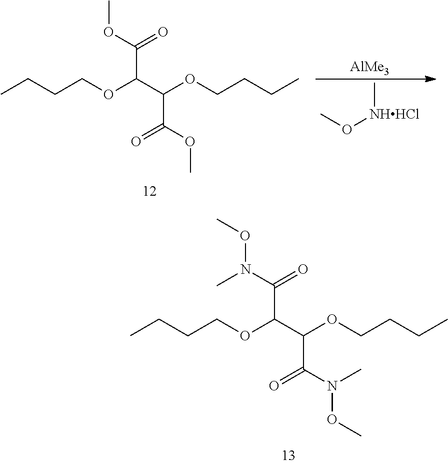

To a DCM solution of N,O-dimethylhydroxylammonium chloride (4.6 eq), 4.5 eq of trimethylaluminum is added slowly at 0° C. Then compound 12 (1.0 eq) is added slowly at 0° C. The solution is reacted at 0° C. for lh, then warmed to room temperature and kept for 1 h. Quench the reaction with 1N HCl solution. An organic phase is extracted from the solution with DCM. The organic phase is collected, and the solvent is removed. The crude product is purified by silica gel chromatography. (yield-60-95%).

Route 4-1B-3^{rd} step: Make a diketone derivative (compound 9)

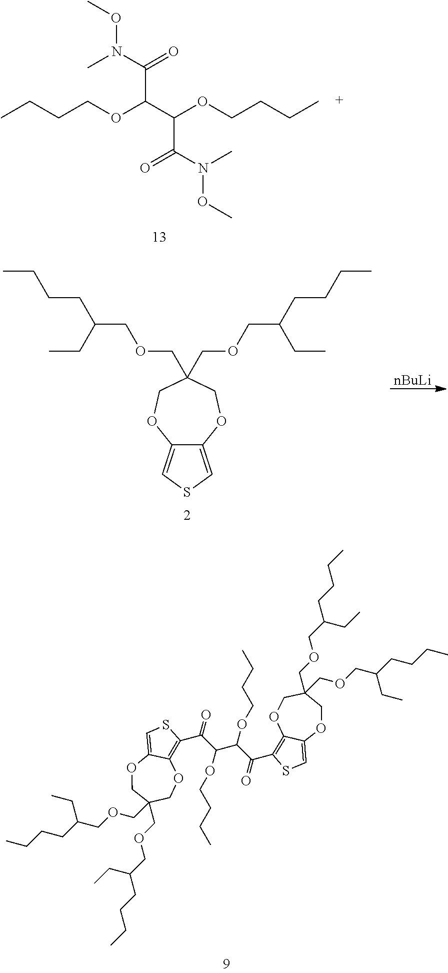

Propylenedioxythiophene(ProDOT) compound 2 (2.6 eq) is added into a Schlenk tube. The tube is kept under vacuum for about 15 minutes and then purged with N₂. The process described above is repeated for three cycles. Then 15mL anhydrous tetrahydrofuran (THF) is added into the tube with a syringe. The solution is kept at −78° C. then 2.5 mL nBuLi solution (2.5M in hexane) is added. Compound 13 is dissolved in 3 mL dry THF and then added into the Schlenk tube at −78° C. The mixture is warmed to room temperature. The reaction is quenched with water, and then an organic phase is extracted from the solution with EtOAc. The organic phase is dried, and the solvent is removed under vacuum. The crude product is purified by silica gel chromatography to get the diketone product compound 9 (yield-60-90%).

Step 4-2: Make the pyrrole derivative-based trimer (compound 10)

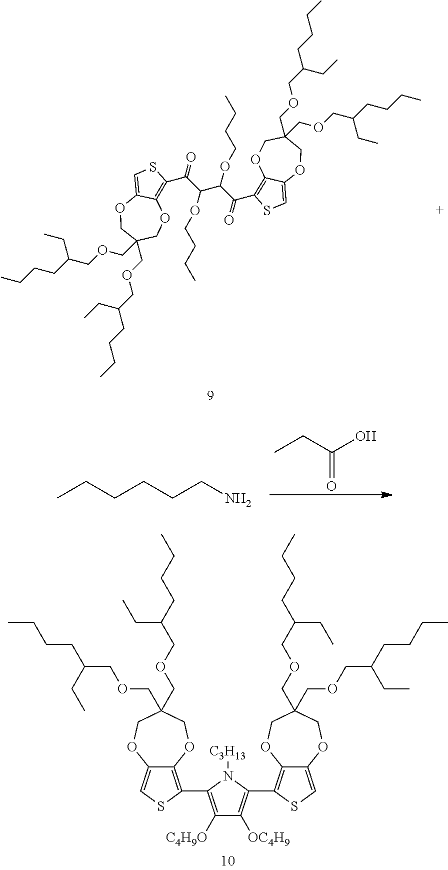

Diketone compound 9 (500 mg, leq), 1-hexanamine (137 mg, 3 eq), propanoic acid (10 mg, 0.3 eq), anhydrous toluene 4 mL are added into a flask. Then the mixture is heated to 110° C. under nitrogen and reacts for 12 hours. The mixture is cooled to room temperature and washed with water. An organic phase is collected, and the solvent is removed with rotovap. The organic phase is purified by silica gel chromatography to get the pyrrole derivative-based trimer (compound 10) (yield-60-90%).

Step 4-3: Make ECP-Yellow 4

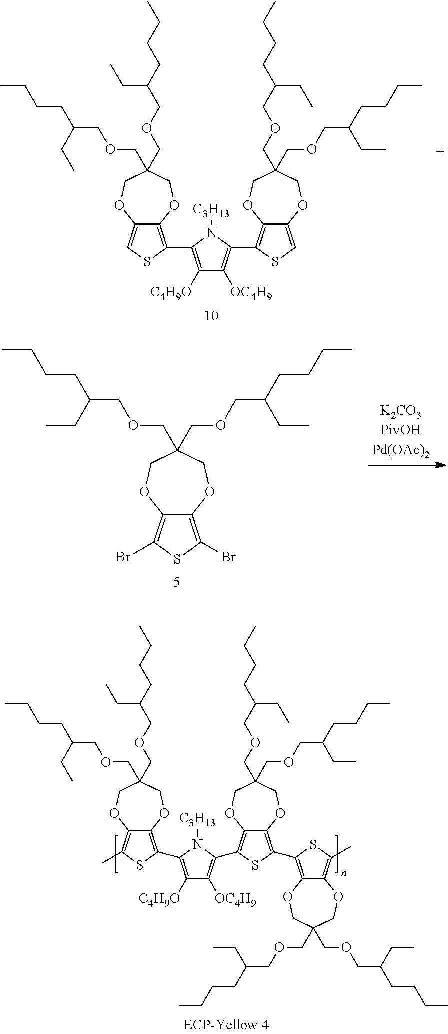

Same as step 1-3, except that Propylenedioxythiophone-2Br (ProDOT-2Br) compound 5 (1.0 eq), pyrrole derivative-base trimer compound 10 (1.0 eq), K₂CO₃ (2.6 eq.), PivOH (0.3 eq.), and Pd(OAc)₂ (0.02 eq.) are added to a Schlenk tube for the reaction.

Embodiment 5—yellow electrochromic polymer (ECP-Yellow 5) formed by alternating polymerization.

In one embodiment, the electrochromic polymer (ECP-Yellow 5) has a formula of

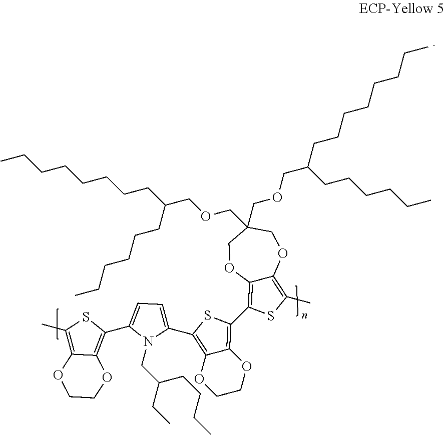

ECP-Yellow 5 is synthesized by preparing a pyrrole derivative-based trimer unit and then polymerizing the pyrrole derivative-based trimer unit with a ProDOT unit. The detailed method includes the following steps:

Step 5-1: Make a diketone derivative product (compound 14).

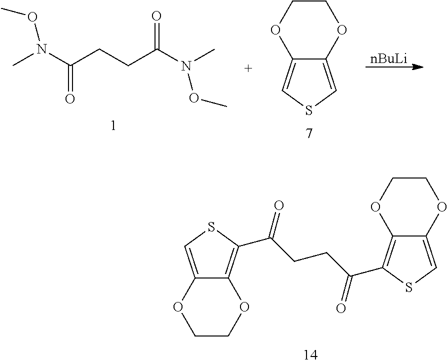

Same as step 1-1, except that 3,4-ethylenedioxythiophene (EDOT) (1.81 g, 2.6 eq) replaces Compound 2 and is added into a schlenk tube.

Step 5-2: Make a pyrrole derivative-based trimer (compound 15)

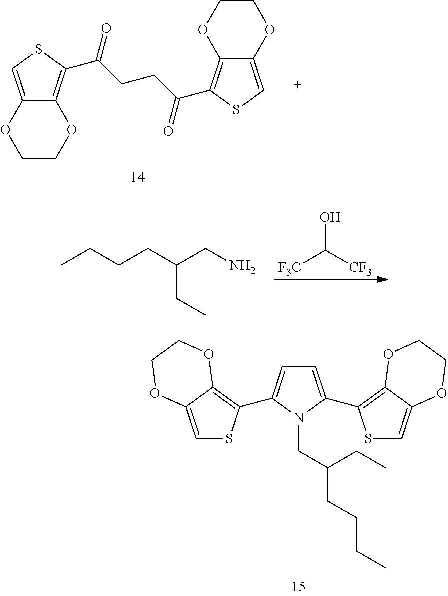

Diketone compound 14 (1.0 g, 1 eq), 2-ethylhexylamine (529 mg, 3 eq), and Hexafluoro-2-propanol 4 mL are added into a flask. Then the mixture is heated to 70° C. under nitrogen and reacts for 12 hours. The mixture is cooling to room temperature and is added with 20 mL DCM and then washed with water. An organic phase is collected, and the solvent is removed with a rotovap. The crude product is purified by silica gel chromatography to get the pyrrole derivative-based trimer (compound 15) (yield-60-90%).

Step 5-3: Make ECP-Yellow 5.

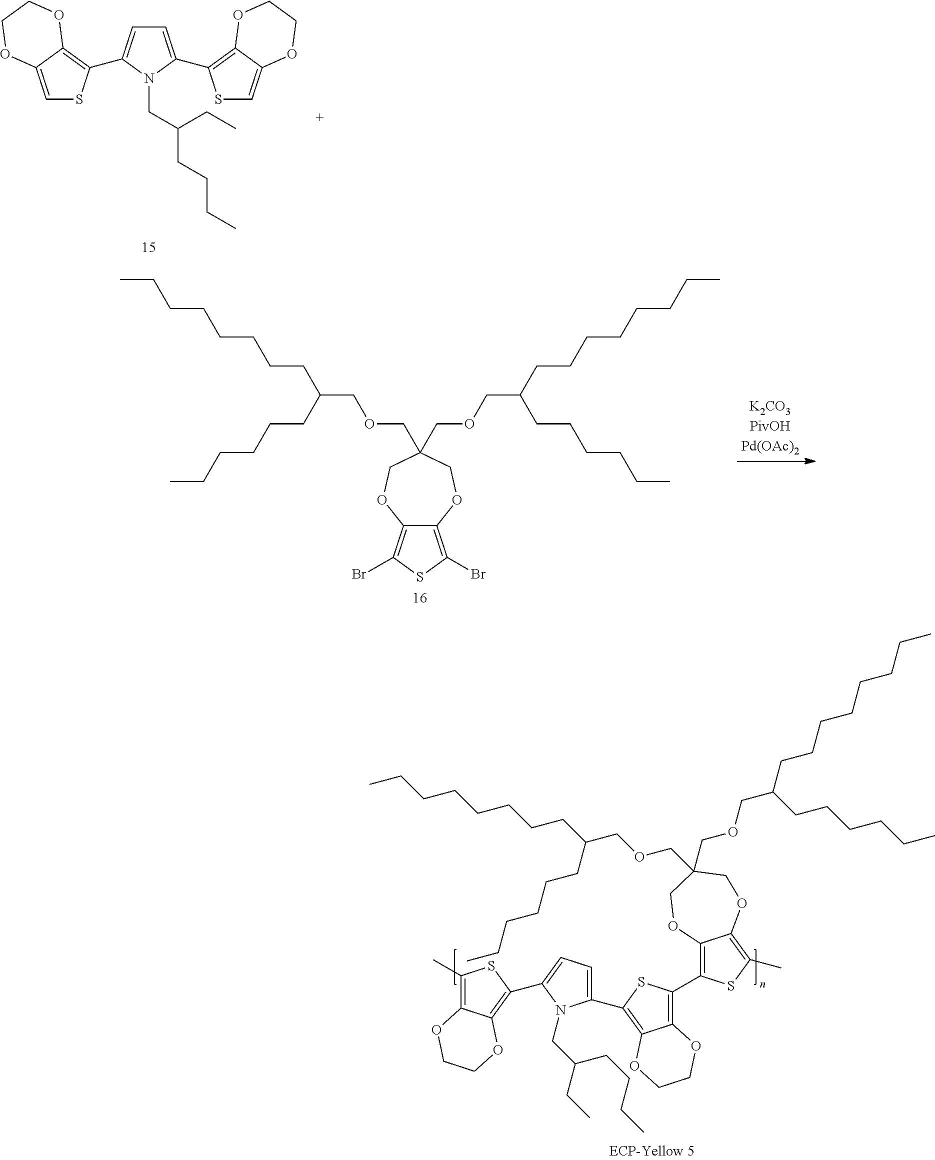

Same as step 1-3, but Propylenedioxythiophene-2Br (ProDOT-2Br) (compound 16, 1.0 eq), pyrrole derivative-based trimer (compound 15, 1.0 eq), K₂CO₃ (2.6 eq.), PivOH (0.3 eq.), and Pd(OAc)₂ (0.02 eq.) are added to a schlenk tube for the reaction.

### Embodiment 6—yellow electrochromic polymer (ECP-Yellow 6) formed by alternating polymerization

In one embodiment, the electrochromic polymer (ECP-Yellow 6) has a formula of

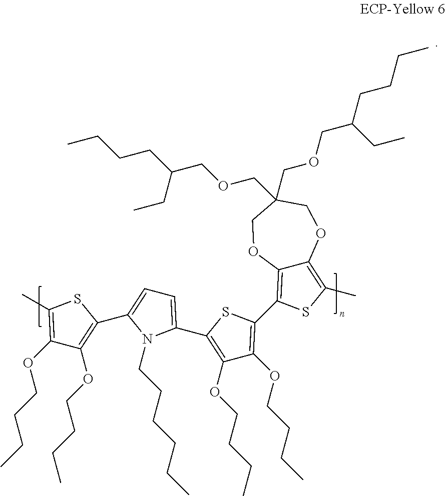

ECP-Yellow 6 is synthesized by preparing a pyrrole derivative-based trimer unit and then polymerizing the pyrrole derivative-based trimer unit with a ProDOT unit. The detailed method includes the following steps:

Step 6-1: Make a diketone derivative (compound 18)

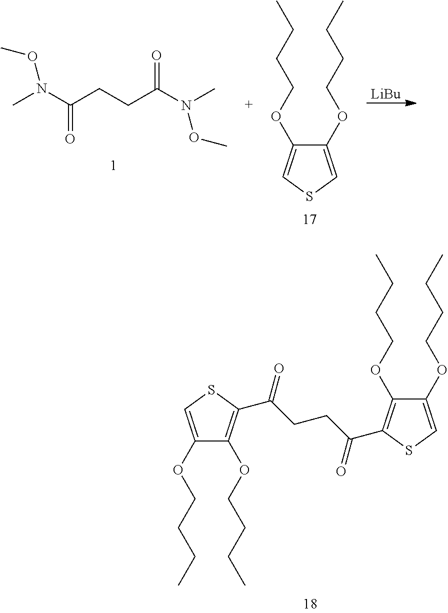

Same as step 1-1, except that Compound 17 (AcDOT) (2.91 g, 2.6 eq) replaces

Compound 2 and is added into a schlenk tube for reaction.

Step 6-2: Make the pyrrole derivative-based trimer (compound 19)

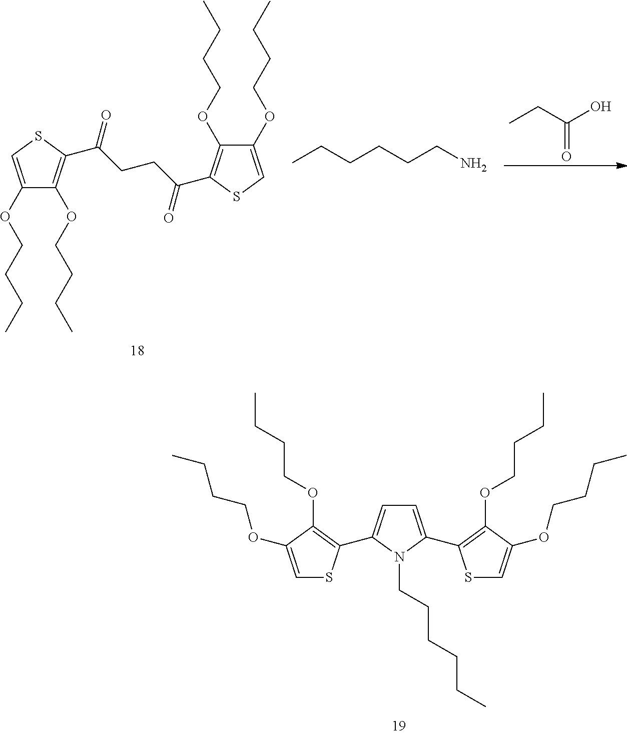

Diketone compound 18 (1.0 g, leq), 1-hexylamine (563 mg, 3eq), propanoic acid (41 mg, 0.3 eq) and anhydrous toluene 4 mL are added into flask. Then the mixture is heated to 110° C. under nitrogen and reacts for 12 hours. The mixture is cooled to room temperature, and then is added with DCM 20 mL and washed with water. An organic phase is collected, and the solvent is removed with a rotovap. The organic phase is purified by silica gel chromatography to get the pyrrole derivative-based trimer compound 19 (yield-60-90%).

Step 6-3: Make ECP-Yellow 6.

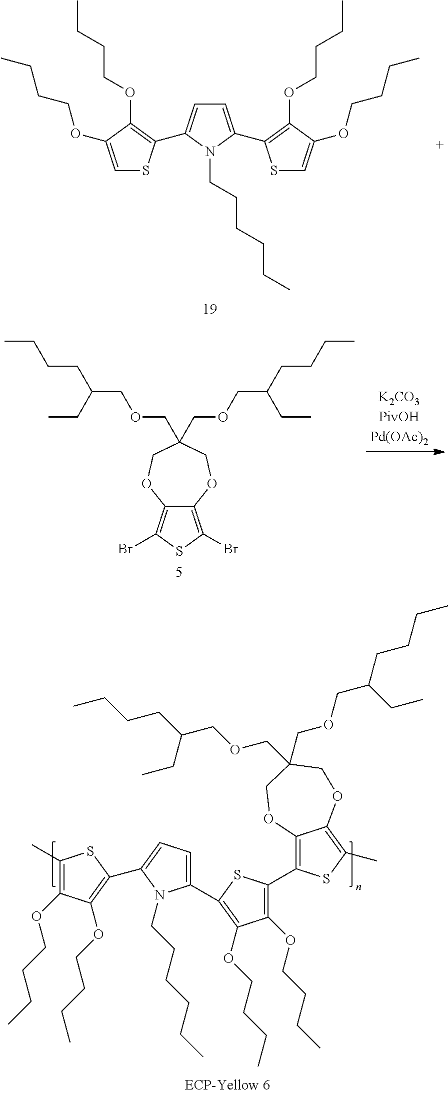

Same as step 1-3, except that Propylenedioxythiophene-2Br (ProDOT-2Br) compound 5 (1.0 eq), pyrrole derivative-based trimer compound 19 (1.0 eq), K₂CO₃ (2.6 eq.), PivOH (0.3 eq.), and Pd(OAc)₂ (0.02 eq.) are added to a schlenk tube for the reaction.

### Embodiment 7—yellow electrochromic polymer (ECP-Yellow 7) formed by random polymerization

In one embodiment, the electrochromic polymer (ECP-Yellow 7) has a formula of

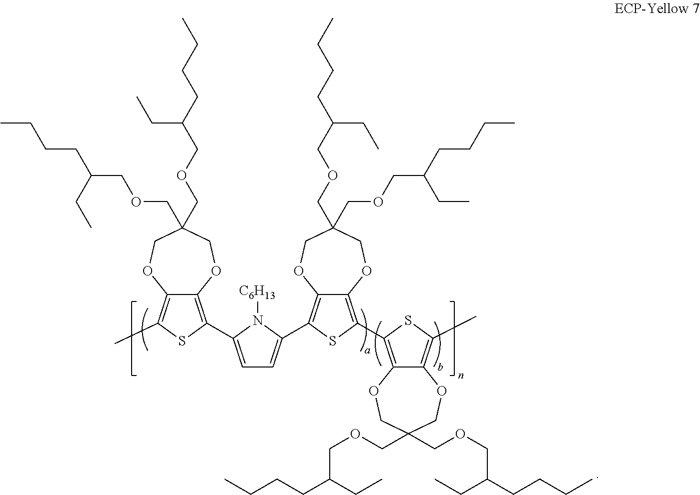

ECP-Yellow 7 is synthesized by preparing a pyrrole derivative-based trimer unit and then polymerizing the pyrrole derivative-based trimer unit with a ProDOT unit. The detailed method includes the following steps:

Step 7-1: Make a diketone derivative (compound 3)

Same as step 1-1.

Step 7-2: Make a pyrrole derivative-based trimer (compound 4)

Same as step 1-2.

Step 7-3: Make ECP-Yellow 7 through 2 different routes

Route 7-3A: Make ECP-Yellow 7

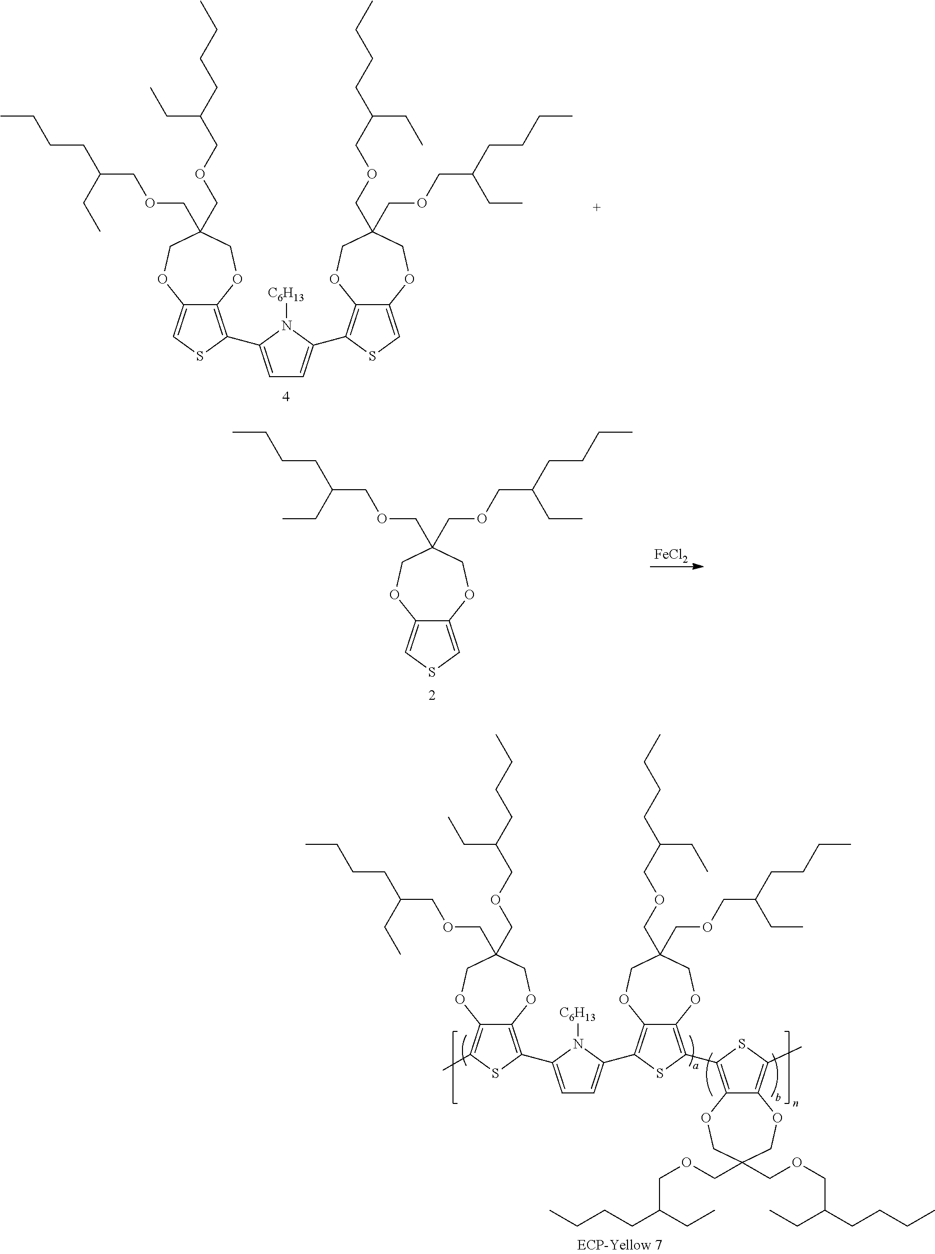

Pyrrole derivative-based trimer compound 4 (1 g, 1.0 eq) and Propylenedioxythiophene(ProDOT) monomer compound 2 (0.428 g, 1.0 eq) are dissolved into 20 mL chloroform at 0° C. 1.58 g FeCl₃ (10 eq) is dissolved into 8 mL nitromethane and then dropped into the chloroform solution with stirring. After reacting for 15 hrs at room temperature, the mixture is dropped into 100 mL methanol to precipitate the resulting polymer. The solid is filtered and washed with 1N HCl and menthanol. Then the solid is put into 40 mL chloroform and reduced with hydrazine. After washing the chloroform solution for 3 times with water, an organic solution was transferred into methanol to precipitate out the polymer product. Filter and dry to get ECP-Yellow 7.

Route 7-3B: Make ECP-Yellow 7

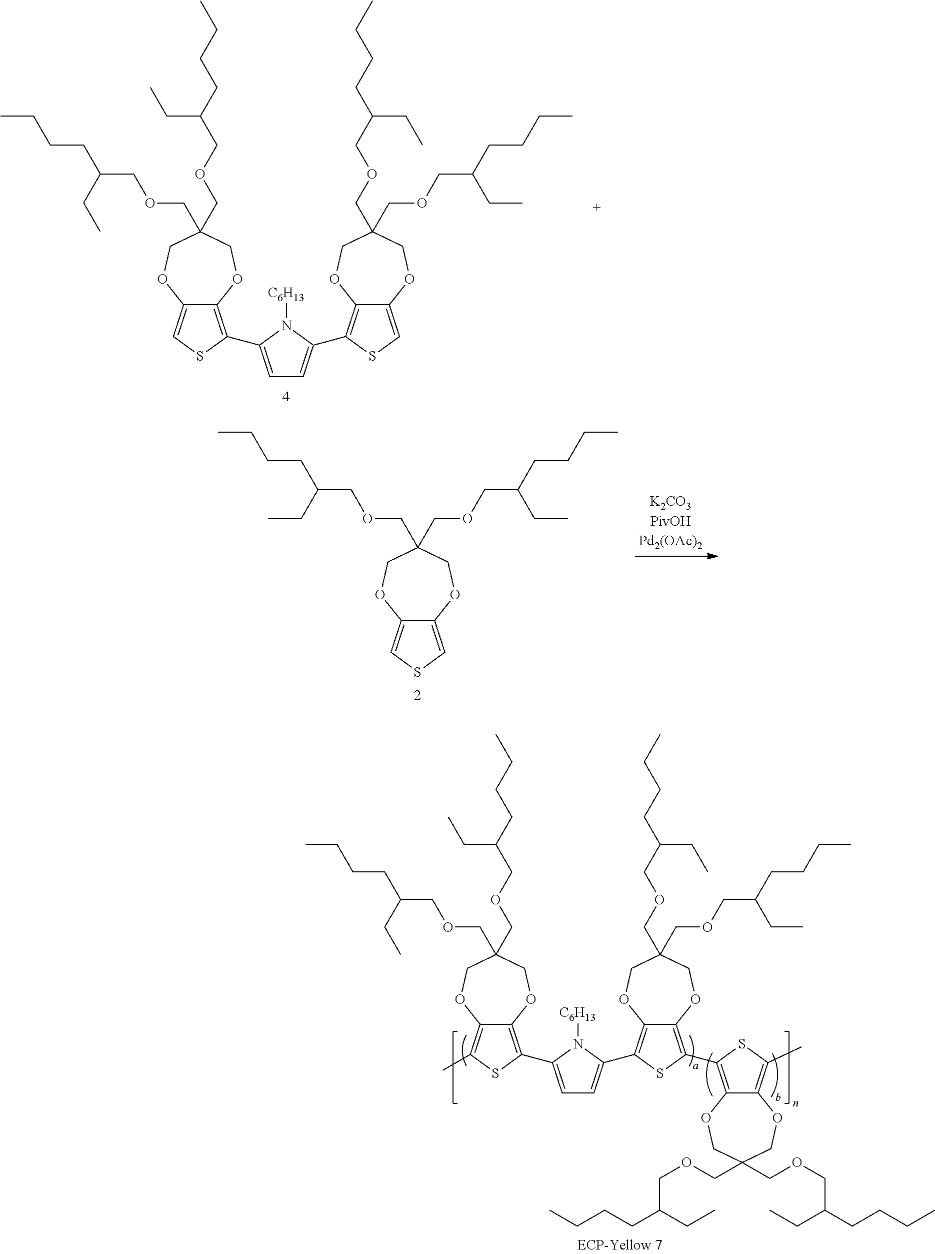

Pyrrole monomer compound 4 (1 g, 1.0 eq), Propylenedioxythiophene (ProDOT) compound 2 (1.0 eq), K₂CO₃ (3.0 eq.), PivOH (1.0 eq.), Pd(OAc)₂ (0.05 eq.), and Ag₂CO₃ (3.0 eq.) are added to a schlenk tube. Dimethylacetamide (DMAc) 10 mL is added into the tube and the mixture is heated at 120° C. for 12 hrs. The hot reaction mixture is transferred to a 1:1 mixture solvent of CH₃OH and 1M HCl with stirring. The mixture is filtered to get the solid. The solid is dissolved in chloroform to form a solution, and then the solution is filtered and washed with 1M HCl solution. An organic phase is concentrated and precipitated with CH₃OH. The organic phase is filtered and dried to get yellow polymer 7. The yield is about 80-100%.

### Embodiment 8—red electrochromic polymer (ECP-Red 1) formed by random polymerization

In one embodiment, the electrochromic polymer (ECP-Red 1) has a formula of

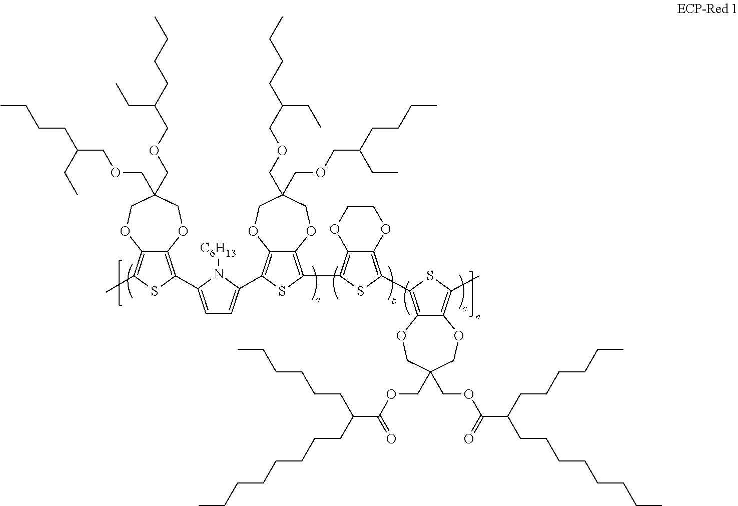

ECP-Red 1 is synthesized by preparing a pyrrole derivative-based trimer unit and then polymerizing the pyrrole derivative-based trimer unit with a EDOT unit and a ProDOT unit. The detailed method includes the following steps:

Step 8-1: Make a diketone derivative (compound 3)

Same as step 1-1.

Step 8-2: Make a pyrrole derivative-based trimer (compound 4)

Same as step 1-2.

Step 8-3: Make ECP-Red 1

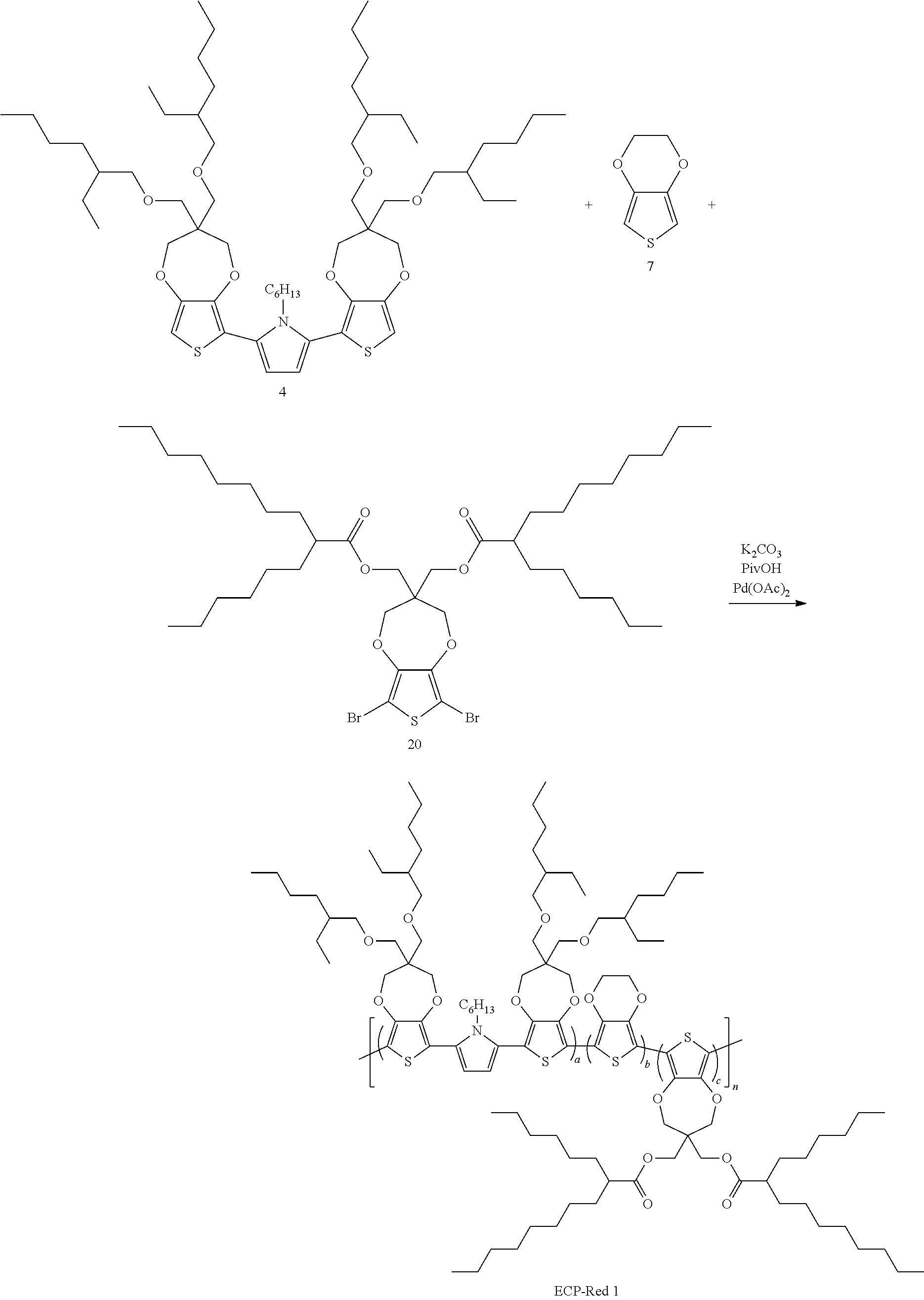

Same as step 1-3, except that Pyrrole derivative-based trimer compound 4 (0.35 eq), Ethylenedioxythiophene (EDOT) compound 7 (0.65 eq), Propylenedioxythiophene(ProDOT) monomer compound 20 (1 eq), K₂CO₃ (2.6 eq.), PivOH (0.3 eq.), and Pd(OAc)₂ (0.02 eq.) are added to a Schlenk tube for the reaction.

The obtained ECP-Red 1 is dissolved in chloroform with a concentration of 20 mg/ml.

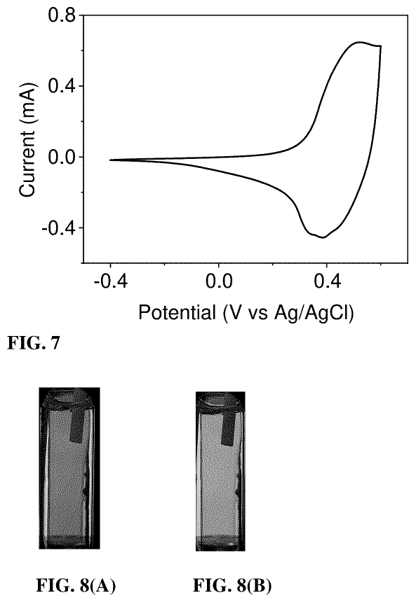

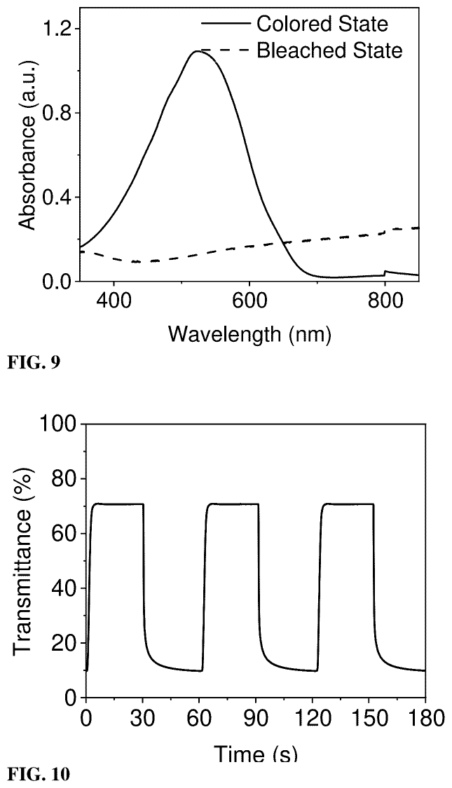

The ECP-Red 1 chloroform solution is spin-coated onto an ITO-coated glass substrate. The performance of the resulting ECP-Red 1 thin film is tested in a three-electrode system with Ag/AgCl as the reference electrode, 0.2 M LiPTFSi/PC as the electrolyte, and Pt wire as the counter electrode. As shown in FIG. 7, the exemplary electrochromic polymer has a very low oxidation onset potential of around 0.3 V vs. Ag/AgCl. And the electrochromic polymer shows red color with maximal absorbance at 524 nm at a colored state and low absorbance within the visible light range (400 nm-800 nm) at a bleached state (shown in FIG. 9). The corresponding images of the ECP-Red 1 thin film at colored and bleached states are shown in FIGS. 8(A) and 8(B). The optimal optical contrast at 550 nm is as high as 61% (shown in FIG. 10).

What is claimed is:

1. An electrochromic polymer comprising a formula of
[(Tr)ₐ-(Ar₁)_{b}-(Ar₂)_{c}-(Ar₃)_{d}]ₙ,
wherein,
Tr is a pyrrole-based or a pyrrole derivative-based trimer with a formula of 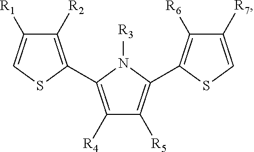
Ar₁ is 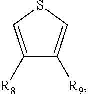
Ar₂ is 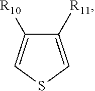
Ar₃ is 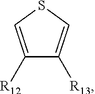
n is an integer greater than 0; a is an integer greater than 0; b, c, and d are integers no less than 0, and a ratio between a and the sum of b, c, and d is between 0.1 to 4 inclusive; and each of R₁-R₁₃ is independently selected from, but not limited to, hydrogen, C₁-C₃₀alkyl, C₂-C₃₀alkenyl, C₂-C₃₀alkynyl, C₂-C₃₀alkylcarbonyl, C₁-C₃₀alkoxy, C₃-C₃₀alkoxyalkyl, C2-C₃₀alkoxycarbonyl, C₄-C₃₀alkoxycarbonylalkyl, C₁-C₃₀alkylthio, C₁-C₃₀aminylcarbonyl, C₄-C₃₀aminylalkyl, C₁-C₃₀alkylaminyl, C1-C₃₀alkylsulfonyl, C₃-C₃₀alkylsulfonylalkyl, C₆-C₁₈aryl, C₃-C₁₅cycloalkyl, C₃-C₃₀cycloalkylaminyl, C₅-C₃₀cycloalkylalkylaminyl, C₅-C₃₀cycloalkylalkyl, C₅-C₃₀cycloalkylalkyloxy, C₁-C₁₂heterocyclyl, C₁-C₁₂heterocyclyloxy, C₃-C₃₀heterocyclylalkyloxy, C₁-C₃₀heterocyclylalkyloxy, C₁-C₃₀heterocyclylaminyl, C₅-C₃₀heterocyclylalkylaminyl, C2-C₁₂ heterocyclylcarbonyl, C₃-C₃₀heterocyclylalkyl, C₁-C₁₃heteroaryl, or C₃-C₃₀heteroarylalkyl.

2. The electrochromic polymer of claim 1, wherein the electrochromic polymer has an oxidation onset potential of lower than 0.6 V with Ag/AgCl as a reference electrode.

3. The electrochromic polymer of claim 1, wherein the electrochromic polymer has an optical contrast of higher than 50% at its maximal absorbance wavelength.

4. The electrochromic polymer of claim 1, wherein the electrochromic polymer has a maximal absorbance wavelength between 400 to 550 nm inclusive.

5. The electrochromic polymer of claim 1, wherein Tr is selected from one of the following formulas: 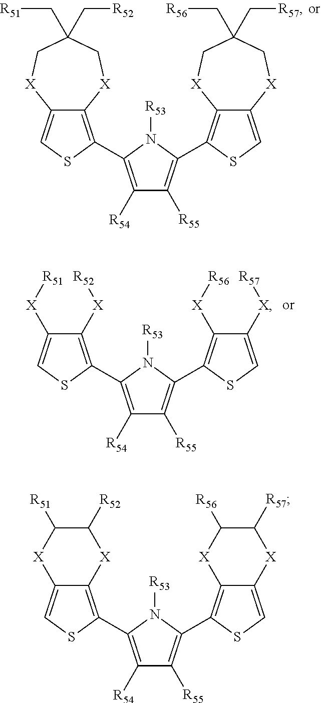
each of Ar₁i Ar₂, and Ar₃ is independently selected from one of the following formulas: 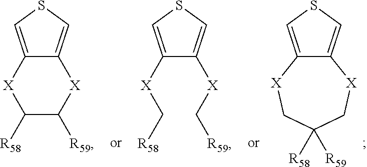
X is S or O; each of R₅₁-R₅₉ is independently selected from, but not limited to, hydrogen, C₁-C₃₀alkyl, C₂-C₃₀alkenyl, C₂-C₃₀alkynyl, C₂-C₃₀alkylcarbonyl, C₁-C₃₀alkoxy, C₃-C₃₀alkoxyalkyl, C₂-C₃₀alkoxycarbonyl, C₄-C₃₀alkoxycarbonylalkyl, C₁-C₃₀alkylthio, C₁-C₃₀aminylcarbonyl, C₄-C₃₀aminylalkyl, C₁-C₃₀alkylaminyl, C₁-C₃₀alkylsulfonyl, C₃-C₃₀alkylsulfonylalkyl, C₆-C₁₈aryl, C₃-C₁₅cycloalkyl, C₃-C₃₀cycloalkylaminyl, C₅-C₃₀cycloalkylalkylaminyl, C₅-C₃₀cycloalkylalkyl, C₅-C₃₀cycloalkylalkyloxy, C₁-C₁₂heterocyclyl, C₁-C₁₂ heterocyclyloxy, C₃-C₃₀heterocyclylalkyloxy, C₁-C₃₀heterocyclylalkyloxy, C₁-C₃₀heterocyclylaminyl, C₅-C₃₀heterocyclylalkylaminyl, C₂-C₁₂heterocyclylcarbonyl, C₃-C₃₀heterocyclylalkyl, C₁-C₁₃heteroaryl, or C₃-C₃₀heteroarylalkyl.

6. The electrochromic polymer of claim 5, wherein X is O.

7. The electrochromic polymer of claim 1, wherein the electrochromic polymer has a formula of

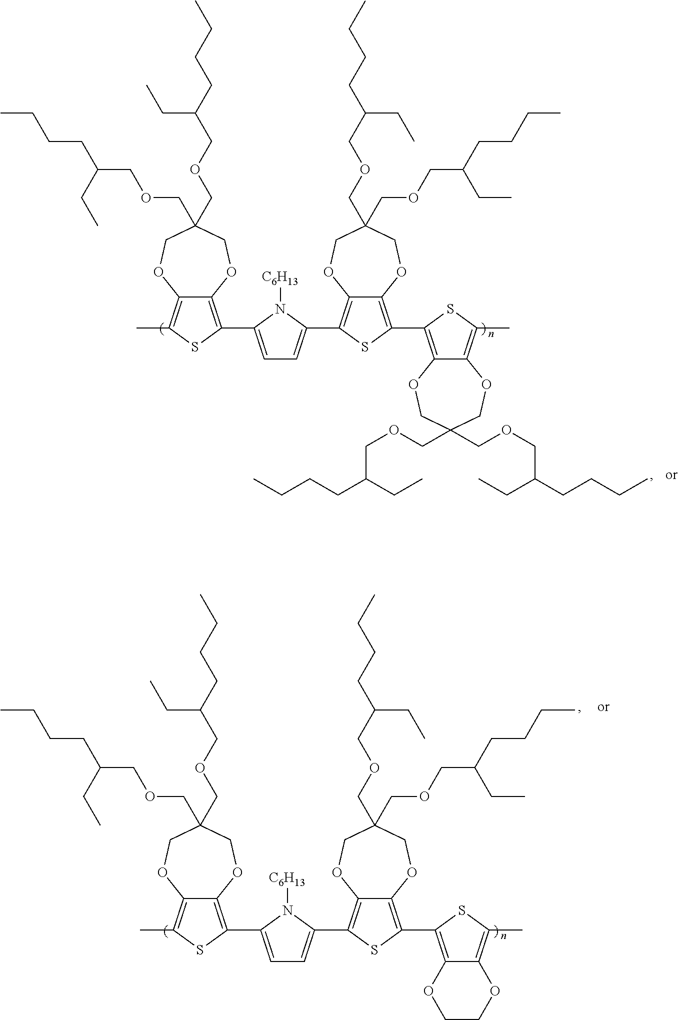

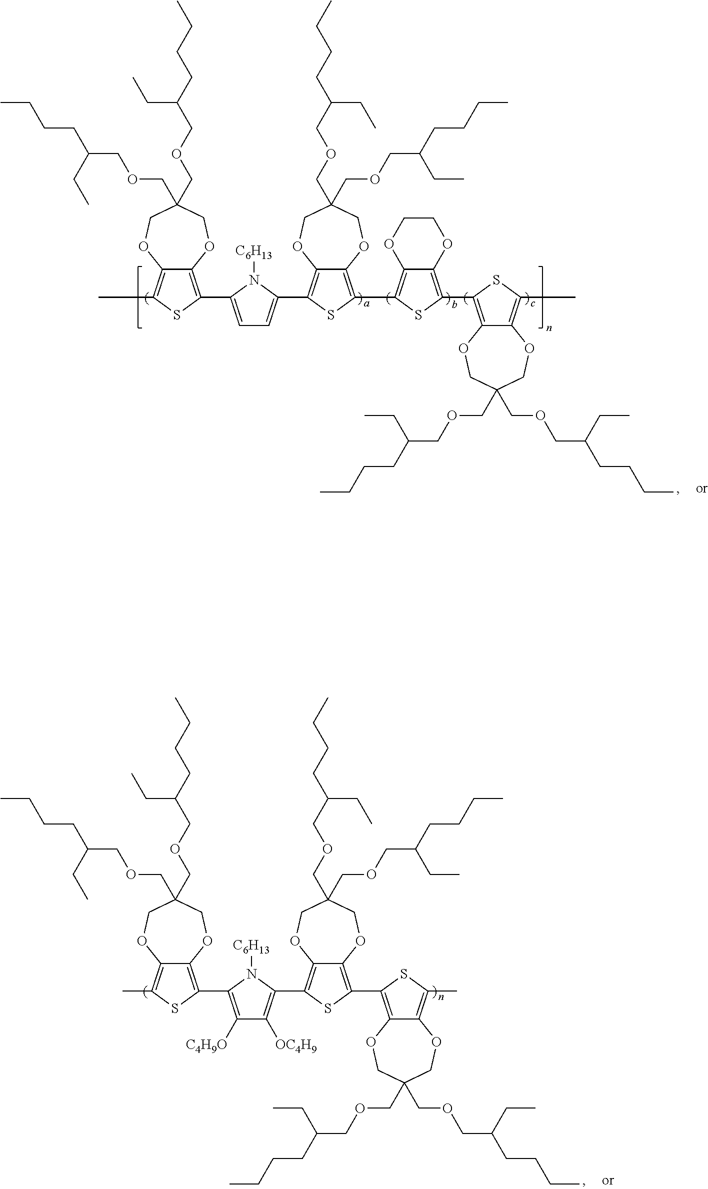

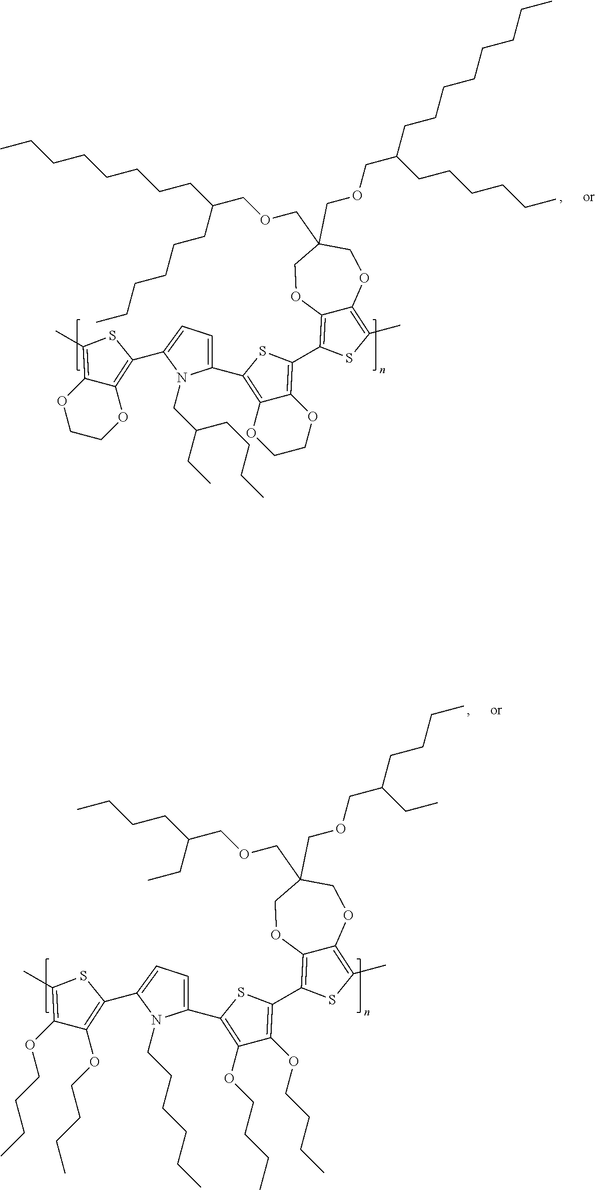

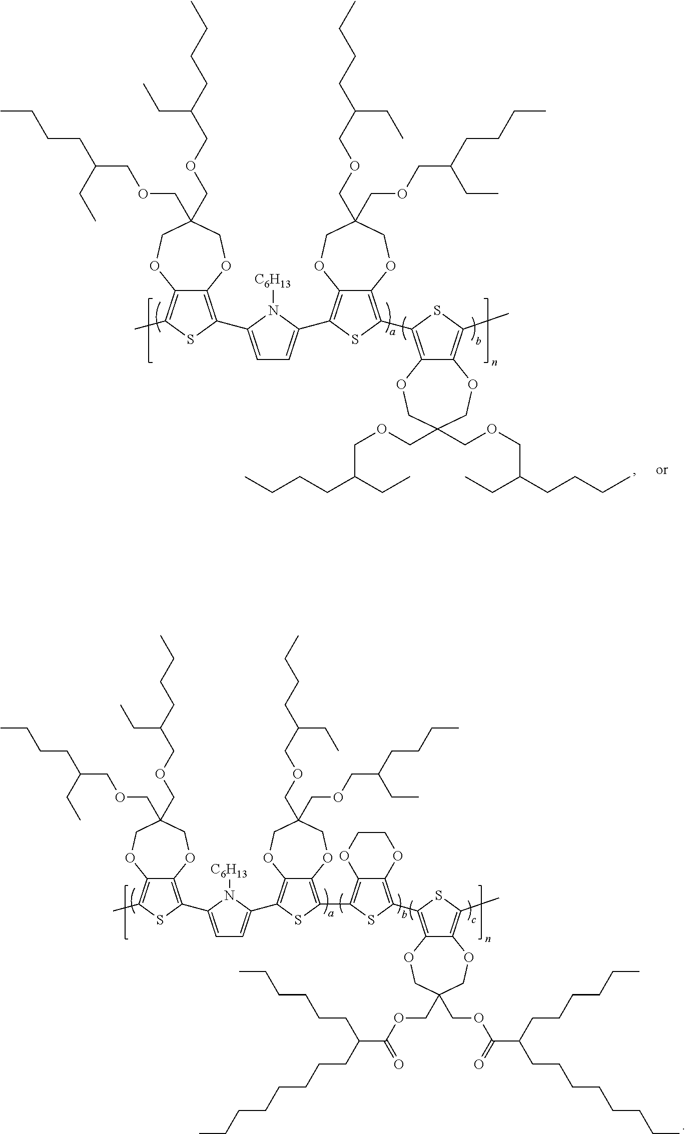

8. A method for forming the electrochromic polymer of claim 1, the method comprising:
preparing pyrrole-based or pyrrole derivative-based thiophene trimer units; preparing the electrochromic polymer by polymerizing the pyrrole-based or pyrrole derivative-based thiophene trimer units with thiophene units.

9. A method for forming diketone derivatives, the method comprising contacting lithiated thiophene derivatives with N1,N4-dimethoxy-N1,N4-dimethylsuccinamide.

10. A method for forming a pyrrole or pyrrole derivative, the method comprising contacting diketone with primary amine in the presence of Hexafluoro-2-propanol.

11. A device incorporating the electrochromic polymer of claim 1.
